(19) United States
(12) Patent Application Publication
(10) Pub. No.: US 2026/0293355 A1
(43) Pub. Date: Sep. 24, 2026

(54) IMAGING DEVICE AND IMAGING METHOD

(71) Applicant: SONY SEMICONDUCTOR SOLUTIONS CORPORATION, Kanagawa (JP)

(72) Inventor: Yuki HATTORI, Kanagawa (JP)

(73) Assignee: SONY SEMICONDUCTOR SOLUTIONS CORPORATION, Kanagawa (JP)

(21) Appl. No.: 19/471,649

(22) PCT Filed: Feb. 16, 2024
(86) PCT No.: PCT/JP2024/005572

§ 371 Date: Oct. 1, 2025

(30) Foreign Application Priority Data
Apr. 13, 2023 (JP) 2023-065296

(51) Int. Cl. H10F 39/00; H04N 25/78

(52) U.S. Cl. CPC H10F 39/811; H04N 25/78; H10F 39/8057

(57) ABSTRACT

The present disclosure enables transmission of signals through a plurality of signal lines while suppressing crosstalk between signals read out from pixels adjacent to each other. An imaging device includes pixels arrayed in a matrix in a row direction and a column direction, and a plurality of signal lines configured to transmit, simultaneously in the column direction, signals read out from pixels belonging to the same column and in mutually different rows. In at least one column, the signal lines and the pixels are connected such that an array order of the signal lines and an array order of the pixels differ from each other. The imaging device may include shield lines disposed between the signal lines. The shield line may be disposed between signal lines adjacent to each other and connected to different color pixels.

### TECHNICAL FIELD

The present technology relates to an imaging device and an imaging method. More specifically, the present technology relates to an imaging device in which a plurality of signal lines are provided in one column and an imaging method.

### BACKGROUND ART

An imaging device in which a plurality of pixels are provided across a plurality of rows and a plurality of columns is known. For example, an imaging device in which a shield wiring line is disposed between signal lines of the plurality of signal lines, and other signal lines of the plurality of signal lines are adjacent to each other has been proposed (for example, refer to PTL 1).

### CITATION LIST

### Patent Literature

PTL 1: JP 2019-102948 A

### SUMMARY

### Technical Problem

However, in the related art described above, signals read out from pixels adjacent to each other are simultaneously transmitted through signal lines adjacent to each other. This may cause an increase in crosstalk between the signals read out from the pixels adjacent to each other.

The present technology has been made in view of such circumstances, and an object thereof is to enable transmission of signals through a plurality of signal lines while suppressing crosstalk between signals read out from pixels adjacent to each other.

### Solution to Problem

The present technology has been made to solve the above-described problem, and a first aspect thereof is an imaging device including pixels arrayed in a matrix in a row direction and a column direction and a plurality of signal lines configured to transmit, simultaneously in the column direction, signals read out from pixels belonging to the same column and in mutually different rows. In at least one column, the signal lines and the pixels are connected such that an array order of the signal lines and an array order of the pixels differ from each other. According to this configuration, an effect of simultaneously transmitting signals through the plurality of signal lines while suppressing crosstalk between signals read out from pixels adjacent to each other is achieved.

Further, in the first aspect, the imaging device may include shield lines disposed between the signal lines. According to this configuration, an effect of suppressing crosstalk between signals transmitted through the signal lines adjacent to each other is achieved.

Further, in the first aspect, a shield line of the shield lines may be disposed between signal lines adjacent to each other and connected to different color pixels. According to this configuration, an effect of suppressing color mixture of signals transmitted through signal lines adjacent to each other is achieved.

Further, in the first aspect, at least one of the shield lines may be connected to a ground potential. According to this configuration, an effect of stabilizing shielding properties of the shield lines is achieved.

Further, in the first aspect, at least one of the shield lines may be connected to a power supply potential. According to this configuration, an effect of disposing the shield lines between the signal lines while suppressing restriction on a layout of a power supply line is achieved.

Further, in the first aspect, at least one of the shield lines may be divided such that a portion connected to a power supply potential is interposed between portions connected to a ground potential. According to this configuration, an effect of stabilizing the shielding properties of the shield lines while suppressing restriction on the layout of the power supply line is achieved.

Further, in the first aspect, the pixels may include different color pixels alternately arrayed in the column direction. According to this configuration, an effect of suppressing color mixture of signals transmitted simultaneously through the plurality of signal lines while adjacently disposing the different color pixels in the column direction is achieved.

Further, in the first aspect, same color pixels configured to be read simultaneously in each column may be connected to signal lines adjacent to each other. According to this configuration, an effect of suppressing crosstalk between signals while simultaneously transmitting signals read out from pixels adjacent to each other through the plurality of signal lines is achieved.

Further, in the first aspect, the signal lines may include a first signal line connected to a first pixel, a second signal line connected to a second pixel adjacent to the first pixel in the column direction, and a third signal line connected to a third pixel and located between the first signal line and the second pixel. According to this configuration, an effect in that pixels adjacent to each other in the column direction are connected to signal lines not adjacent to each other is achieved.

Further, in the first aspect, the pixels may include a first pixel, a second pixel, and a third pixel sequentially arrayed in the column direction, the signal lines may include a first signal line, a second signal line, and a third signal line sequentially arrayed in the row direction, the first pixel may be connected to the first signal line, the second pixel may be connected to the third signal line, and the third pixel may be connected to the second signal line. According to this configuration, an effect in that pixels adjacent to each other in the column direction are connected to signal lines not adjacent to each other is achieved.

Further, in the first aspect, the first pixel and the third pixel may be same color pixels, and the first pixel and the second pixel may be different color pixels. According to this configuration, an effect of suppressing color mixture of signals transmitted simultaneously through the plurality of signal lines while alternately disposing different color pixels in the column direction is achieved.

Further, in the first aspect, readout of signals from the first pixel, the second pixel, and the third pixel may be implemented simultaneously. According to this configuration, an effect of simultaneously transmitting signals read out from different color pixels through the plurality of signal lines while suppressing color mixture is achieved.

Further, in the first aspect, the pixels adjacent to each other may be connected to the same signal line. According to this configuration, an effect of transmitting signals read out from adjacent pixels through the same signal line is achieved.

Further, in the first aspect, the signal lines may include a first signal line connected to a first pixel and a second pixel adjacent to each other in the column direction, a second signal line connected to a third pixel and a fourth pixel adjacent to each other in the column direction, and a third signal line connected to a fifth pixel and a sixth pixel adjacent to each other in the column direction and located between the first signal line and the second pixel. According to this configuration, an effect in that pixels adjacent to each other at every other position in the column direction are connected to signal lines not adjacent to each other while connecting pixels adjacent to each other in the column direction to the same signal line is achieved.

Further, in the first aspect, the pixels may include a first pixel, a second pixel, a third pixel, a fourth pixel, a fifth pixel, and a sixth pixel sequentially arrayed in the column direction, the signal lines may include a first signal line, a second signal line, and a third signal line sequentially arrayed in the row direction, the first pixel and the second pixel may be connected to the first signal line, the third pixel and the fourth pixel may be connected to the third signal line, and the fifth pixel and the sixth pixel may be connected to the second signal line. According to this configuration, an effect in that pixels adjacent to each other at every other position in the column direction are connected to signal lines not adjacent to each other while connecting pixels adjacent to each other in the column direction to the same signal line is achieved.

Further, in the first aspect, readout of signals from the first pixel, the third pixel, and the fifth pixel may be simultaneously implemented at a first timing, and readout of signals from the second pixel, the fourth pixel, and the sixth pixel may be simultaneously implemented at a second timing. According to this configuration, an effect of reading out signals from pixels connected to the same signal line and adjacent to each other in the column direction at mutually different timings is achieved.

Further, in the first aspect, the first pixel, the third pixel, and the fifth pixel may be same color pixels, the second pixel, the fourth pixel, and the sixth pixel may be same color pixels, and the first pixel and the second pixel may be different color pixels. According to this configuration, an effect of transmitting signals read out from the different color pixels at mutually different timings through the plurality of signal lines while alternately disposing different color pixels in the column direction is achieved.

Further, a second aspect is an imaging method including reading out signals from, among pixels arrayed in a matrix in a row direction and a column direction, pixels belonging to the same column and in mutually different rows, and simultaneously transmitting, in the column direction, the signals read out from the pixels belonging to the same column and in mutually different rows, through a plurality of signal lines connected to the pixels in an array order mutually different from an array order of the pixels. According to this configuration, an effect of simultaneously transmitting signals through the plurality of signal lines while suppressing crosstalk between signals read out from pixels adjacent to each other is achieved.

Further, in the second aspect, pixels adjacent to each other in the column direction may be different color pixels. According to this configuration, an effect of suppressing color mixture of signals transmitted simultaneously through the plurality of signal lines while adjacently disposing the different color pixels in the column direction is achieved.

Further, in the second aspect, a readout timing from each of the pixels may be set such that different color pixels are read out at mutually different timings in each column. According to this configuration, an effect of suppressing the color mixture of signals read out from different color pixels while connecting the different color pixels to signal lines adjacent to each other is achieved.

### BRIEF DESCRIPTION OF DRAWINGS

FIG. 1 is a block diagram depicting a configuration example of an imaging device according to a first embodiment.

FIG. 2 is a block diagram depicting a configuration example of a solid-state imaging device according to the first embodiment.

FIG. 3 is a block diagram depicting a circuit configuration example of a pixel provided in the solid-state imaging device according to the first embodiment.

FIG. 4 is a diagram depicting an example of connection between pixels and vertical signal lines according to the first embodiment.

FIG. 5 is a diagram depicting an example of crosstalk of a defective pixel according to the first embodiment.

FIG. 6 is a block diagram depicting transmission paths of signals read out from pixels at a first timing according to the first embodiment.

FIG. 7 is a block diagram depicting transmission paths of signals read out from pixels at a second timing according to the first embodiment.

FIG. 8 is a perspective view depicting a layout example of the pixels and the vertical signal lines according to the first embodiment.

FIG. 9 is a block diagram depicting transmission paths of signals read out from pixels at a first timing according to a second embodiment.

FIG. 10 is a block diagram depicting transmission paths of signals read out from pixels at a second timing according to the second embodiment.

FIG. 11 is a diagram depicting an example of connection between the pixels and the vertical signal lines according to a third embodiment.

FIG. 12 is a diagram depicting an example of crosstalk of a defective pixel according to the third embodiment.

FIG. 13 is a block diagram depicting transmission paths of signals read out from pixels at a first timing according to the third embodiment.

FIG. 14 is a block diagram depicting transmission paths of signals read out from pixels at a second timing according to the third embodiment.

FIG. 15 is a diagram depicting an example of connection between the pixels and the vertical signal lines according to a fourth embodiment.

FIG. 16 is a diagram depicting an example of connection between the pixels and the vertical signal lines according to a fifth embodiment.

FIG. 17 is a diagram depicting a configuration example of a pixel array section according to a sixth embodiment.

FIG. 18 is a diagram depicting a configuration example of a pixel array section according to a seventh embodiment.

FIG. 19 is a diagram depicting a configuration example of a pixel array section according to an eighth embodiment.

FIG. 20 is a diagram depicting a configuration example of a pixel according to a ninth embodiment.

FIG. 21 is a timing chart depicting waveforms of respective sections during readout from the pixel according to the ninth embodiment.

FIG. 22 is a diagram depicting a configuration example of a pixel according to a tenth embodiment.

FIG. 23 is a timing chart depicting waveforms of respective sections during readout from the pixel according to the tenth embodiment.

FIG. 24 is a perspective view depicting a layering example of a solid-state imaging device according to an eleventh embodiment.

FIG. 25 is a block diagram depicting a schematic configuration example of a vehicle control system.

FIG. 26 is an explanatory view depicting an example of an installation position of an imaging section.

### DESCRIPTION OF EMBODIMENTS

Hereinafter, modes for carrying out the present technology (hereinafter, referred to as embodiments) will be described. Description will be made in the following order.
1. First Embodiment (example in which vertical signal lines and pixels are connected such that an array order of four vertical signal lines and an array order of the pixels provided in one column differ from each other, and signals read out from different color pixels at the same timing are transmitted in opposite directions)
2. Second Embodiment (example in which vertical signal lines and pixels are connected such that an array order of four vertical signal lines and an array order of the pixels provided in one column are equal to each other, and signals read out from different color pixels at the same timing are transmitted in opposite directions)
3. Third Embodiment (example in which vertical signal lines and pixels are connected such that an array order of four vertical signal lines and an array order of the pixels provided in one column differ from each other, and a readout timing from each pixel is set such that different color pixels are read out at mutually different timings in each column)
4. Fourth Embodiment (example in which vertical signal lines and pixels are connected such that an array order of six vertical signal lines and an array order of the pixels provided in one column differ from each other)
5. Fifth Embodiment (example in which vertical signal lines and pixels are connected such that an array order of six vertical signal lines and an array order of the pixels provided in one column differ from each other, and a readout timing from each pixel is set such that different color pixels are read out at mutually different timings in each column)
6. Sixth Embodiment (example in which a shield line connected to a ground potential is disposed between vertical signal lines)
7. Seventh Embodiment (example in which a shield line connected to a power supply potential is disposed between vertical signal lines)
8. Eighth Embodiment (example in which a shield line is divided such that, at a shield line disposed between vertical signal lines, a portion connected to a power supply potential is interposed between portions connected to a ground potential)
9. Ninth Embodiment (example of a pixel that can switch conversion efficiency)
10. Tenth Embodiment (example in which photodiodes having mutually different sensitivities are provided in a pixel)
11. Eleventh Embodiment (example in which semiconductor chips forming a solid-state imaging device are layered)
12. Application Example of Mobile Body

### 1. First Embodiment

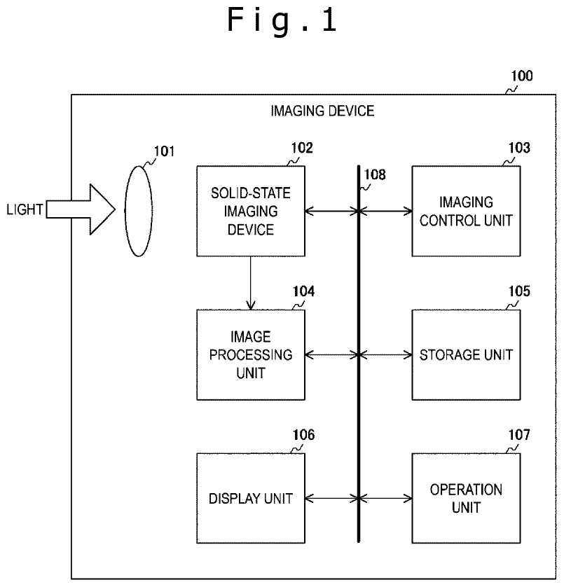

FIG. 1 is a block diagram depicting a configuration example of an imaging device to which an imaging device according to a first embodiment is applied.

In FIG. 1, an imaging device 100 includes an optical system 101, a solid-state imaging device 102, an imaging control unit 103, an image processing unit 104, a storage unit 105, a display unit 106, and an operation unit 107. The imaging control unit 103, the image processing unit 104, the storage unit 105, the display unit 106, and the operation unit 107 are connected to each other via a bus 108. Note that the imaging device 100 may be used as a single body, may be incorporated into a mobile terminal such as a smartphone, or may be incorporated into an authentication device or a monitoring device.

The optical system 101 causes light from a subject to be incident on the solid-state imaging device 102, and forms a subject image on a light-receiving surface of the solid-state imaging device 102. The optical system 101 may include, for example, a focus lens, a zoom lens, a diaphragm, and the like. The optical system 101 may include a plurality of lenses such as a wide-angle lens, a standard lens, and a telephoto lens.

The solid-state imaging device 102 converts the light from the subject into an electric signal for each pixel, digitizes the electric signal, and outputs the digitized electric signal. The solid-state imaging device 102 may be, for example, a complementary metal oxide semiconductor (CMOS) image sensor, may be a charge coupled device (CCD), or may be an event-based vision sensor.

The imaging control unit 103 controls imaging by the solid-state imaging device 102 on the basis of a command from the operation unit 107. At this time, the imaging control unit 103 can control an exposure time, an exposure amount, an imaging timing, and the like of the solid-state imaging device 102.

The image processing unit 104 implements image processing on the basis of an output from the solid-state imaging device 102. The image processing includes, for example, gamma correction, white balance processing, sharpness processing, and gradation conversion processing. The image processing unit 104 may include a processor that executes processing on the basis of software.

The storage unit 105 stores an imaged image imaged by the solid-state imaging device 102, and stores imaging parameters and the like of the solid-state imaging device 102. In addition, the storage unit 105 can store a program for operating the imaging device 100 on the basis of software. The storage unit 105 may include a read only memory (ROM), a random access memory (RAM), and a memory card.

The display unit 106 displays an imaged image and various types of information for supporting an imaging operation. The display unit 106 may be a liquid crystal display or may be an organic electro-luminescence (EL) display.

The operation unit 107 provides a user interface for operating the imaging device 100. The operation unit 107 may include, for example, a button, a dial, and a switch provided in the imaging device 100. The operation unit 107 may be constituted of a touch panel together with the display unit 106.

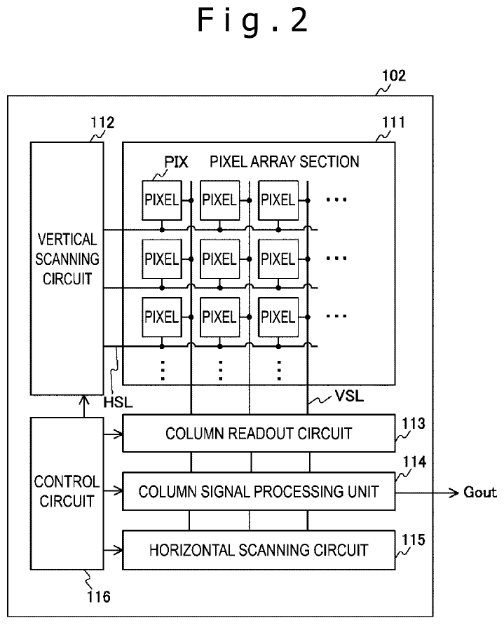

FIG. 2 is a block diagram depicting a configuration example of the solid-state imaging device according to the first embodiment.

In FIG. 2, the solid-state imaging device 102 includes a pixel array section 111, a vertical scanning circuit 112, a column readout circuit 113, a column signal processing unit 114, a horizontal scanning circuit 115, and a control circuit 116.

The pixel array section 111 includes a plurality of pixels PIX. The pixels PIX are arrayed in a matrix in a row direction (also referred to as horizontal direction) and a column direction (also referred to as vertical direction). Each pixel PIX can form a source follower with the column readout circuit 113 during signal readout. Each pixel PIX is connected to a horizontal drive line HSL on a per row basis and is connected to a vertical signal line VSL on a per column basis. The horizontal drive line HSL drives each pixel PIX on a per row basis during signal readout from each pixel PIX. The vertical signal line VSL transmits the signals read out from the pixels PIX to the column signal processing unit 114 on a per column basis.

The pixel array section 111 can include a plurality of the vertical signal lines VSL in each column. Here, the vertical signal line VSL can simultaneously transmit signals read out from the pixels PIX in mutually different rows in the column direction. At this time, in at least one column, the vertical signal lines VSL and the pixels PIX are connected such that an array order of the vertical signal lines VSL and an array order of the pixels PIX differ from each other. Note that the vertical signal line VSL is an example of a signal line described in the scope of the claims.

The imaged image generated by the solid-state imaging device 102 may be colored. In this case, the pixels PIX may include different color pixels alternately arrayed in the column direction. For example, the pixels PIX may form a Bayer array. At this time, same color pixels configured to be read out simultaneously in each column can be connected to the vertical signal lines VSL adjacent to each other. Further, different color pixels configured to be read simultaneously in each column can be connected to the vertical signal lines VSL not adjacent to each other. Further, in each column, in an arrangement in which the vertical signal lines VSL connected to different color pixels configured to be simultaneously read out are adjacent to each other, a shield line may be disposed between the vertical signal lines VSL.

The vertical scanning circuit 112 scans, in the column direction, the pixels PIX to be read out. The vertical scanning circuit 112 may be configured by using a vertical register. Here, the vertical scanning circuit 112 can drive the pixels PIX on a per row basis via the horizontal drive line HSL during signal readout from each pixel PIX. At this time, the vertical scanning circuit 112 can drive the pixels PIX on a per row basis via the horizontal drive line HSL such that signals are simultaneously read out from the pixels PIX of mutually different rows corresponding to the number of the plurality of vertical signal lines VSL of each column.

The column readout circuit 113 can form a source follower with each pixel PIX during signal readout from each pixel PIX. At this time, the column readout circuit 113 can change a potential of the vertical signal line VSL on the basis of a charge held in the pixel PIX. The column readout circuit 113 may support constant current readout or may support capacitive load readout.

The column signal processing unit 114 processes signals transmitted from each pixel PIX in the column direction. For example, the column signal processing unit 114 can implement correlated double sampling (CDS) processing on the basis of the signals transmitted from each pixel PIX in the column direction. The column signal processing unit 114 can implement analog-to-digital (AD) conversion processing on the basis of signals transmitted from each pixel PIX in the column direction and output an imaging signal Gout. At this time, the column signal processing unit 114 can implement the AD conversion processing in parallel for each vertical signal line VSL.

The column signal processing unit 114 can implement defect correction. For example, the column signal processing unit 114 can interpolate a signal read out from a white point pixel with signals read out from pixels around the white point pixel.

The horizontal scanning circuit 115 scans, in the row direction, the pixels PIX to be read. The horizontal scanning circuit 115 may be configured by using a horizontal register.

The control circuit 116 controls the vertical scanning circuit 112, the column readout circuit 113, the column signal processing unit 114, and the horizontal scanning circuit 115. For example, the control circuit 116 can control a scanning timing in the column direction, a scanning timing in the row direction, an operation timing of the column readout circuit 113, and a processing timing of the column signal processing unit 114.

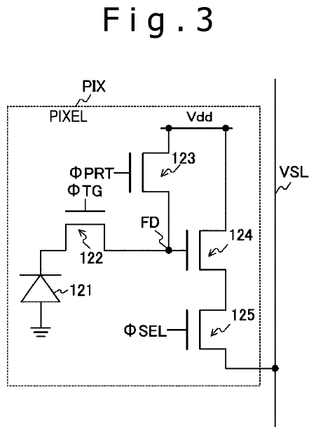

FIG. 3 is a block diagram depicting a circuit configuration example of a pixel provided in the solid-state imaging device according to the first embodiment.

In FIG. 3, the pixel PIX includes a photodiode 121, a transfer transistor 122, a reset transistor 123, an amplification transistor 124, a selection transistor 125, and a floating diffusion FD. As the transfer transistor 122, the reset transistor 123, the amplification transistor 124, and the selection transistor 125, a metal oxide semiconductor (MOS) transistor can be used.

The amplification transistor 124 and the selection transistor 125 are connected in series. A cathode of the photodiode 121 is connected to the floating diffusion FD via the transfer transistor 122. The floating diffusion FD is connected to a power supply Vdd via the reset transistor 123. Further, the power supply Vdd is connected to the vertical signal line VSL via a series circuit of the amplification transistor 124 and the selection transistor 125. A gate of the amplification transistor 124 is connected to the floating diffusion FD.

A transfer signal ΦTG is applied to a gate of the transfer transistor 122. A pixel reset signal ΦPRT is applied to a gate of the reset transistor 123. A selection signal DSEL is applied to a gate of the selection transistor 125. The transfer signal ΦTG, the pixel reset signal ΦPRT, and the selection signal ΦSEL can be transmitted to each pixel PIX via the horizontal drive line HSL in FIG. 2.

When the transfer transistor 122 is turned on, the charge accumulated in the photodiode 121 is transferred to the floating diffusion FD. Then, when the selection transistor 125 is turned on, the source potential of the amplification transistor 124 changes in accordance with the potential of the floating diffusion FD. Then, the source potential of the amplification transistor 124 is applied to the vertical signal line VSL via the selection transistor 125 and transmitted via the vertical signal line VSL. Further, when the reset transistor 123 is turned on, the charge accumulated in the floating diffusion FD is discharged.

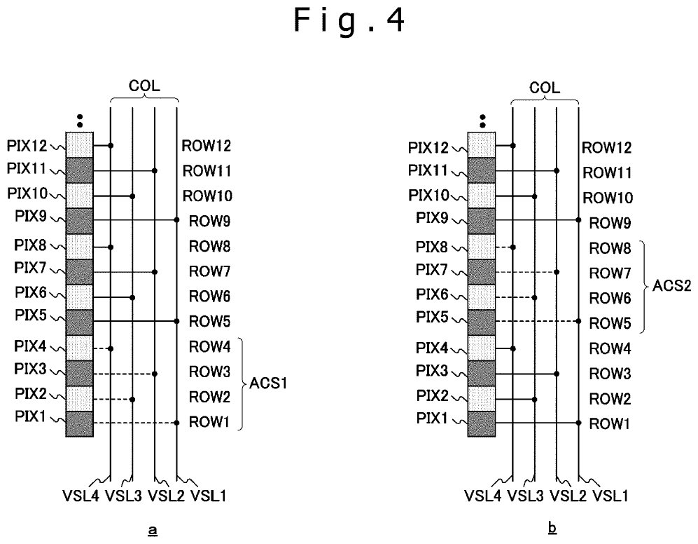

FIG. 4 is a diagram depicting an example of connection between the pixels and the vertical signal lines according to the first embodiment. Note that a in the drawing indicates a connection relationship between the pixels of four rows accessed at a first timing and the vertical signal lines, and b in the drawing indicates a connection relationship between the pixels of four rows accessed at a second timing and the vertical signal lines.

In the drawing, four vertical signal lines VSL1 to VSL4 are provided in each column COL. At this time, the vertical signal lines VSL1 to VSL4 can simultaneously transmit signals read out from four different rows in the column direction.

In each column COL, pixels PIX1 to PIX12 are disposed in the column direction. At this time, the pixels PIX1 to PIX12 may be located in rows ROW1 to ROW12. Further, in each column COL, different color pixels can be adjacently disposed in the column direction. For example, in a Bayer array, the pixels PIX1, PIX3, PIX5, PIX7, PIX9, and PIX11 can be red pixels, and the pixels PIX2, PIX4, PIX6, PIX8, PIX10, and PIX12 can be green pixels. The pixels PIX1, PIX3, PIX5, PIX7, PIX9, and PIX11 may be green pixels, and the pixels PIX2, PIX4, PIX6, PIX8, PIX10, and PIX12 may be blue pixels.

Here, the vertical signal lines VSL1 to VSL4 are connected to the pixels PIX such that the array order of the vertical signal lines VSL and the array order of the pixels PIX in each column COL differ from each other. For example, the pixels PIX1, PIX5, and PIX9 can be connected to the vertical signal line VSL1, and the pixels PIX3, PIX7, and PIX11 can be connected to the vertical signal line VSL2. The pixels PIX2, PIX6, and PIX10 can be connected to the vertical signal line VSL3, and the pixels PIX4, PIX8, and PIX12 can be connected to the vertical signal line VSL4. At this time, the pixels PIX1, PIX3, PIX5, PIX7, PIX9, and PIX11 of the same color are alternately connected to the vertical signal lines VSL1 and VSL2 adjacent to each other. Further, the pixels PIX2, PIX4, PIX6, PIX8, PIX10, and PIX12 of the same color are alternately connected to the vertical signal lines VSL3 and VSL4 adjacent to each other.

In the signal readout, at the first timing, as depicted in a of the drawing, an access ACS1 is implemented in the pixels PIX1 to PIX4 belonging to the respective rows ROW1 to ROW4. At this time, the signals read out from the pixels PIX1 to PIX4 are simultaneously transmitted in the column direction via the vertical signal lines VSL1, VSL3, VSL2, and VSL4, respectively. Further, at the second timing, as illustrated in b of the drawing, an access ACS2 is implemented in the pixels PIX5 to PIX8 belonging to the respective rows ROW5 to ROW8. At this time, the signals read out from the pixels PIX5 to PIX8 are simultaneously transmitted in the column direction via the vertical signal lines VSL1, VSL3, VSL2, and VSL4, respectively.

Here, through the vertical signal lines VSL1 and VSL2 adjacent to each other, signals read out from same color pixels (red pixels, for example) are transmitted, making it possible to suppress color mixture. Further, through the vertical signal lines VSL3 and VSL4 adjacent to each other, signals read out from same color pixels (green pixels, for example) are transmitted, making it possible to suppress color mixture. On the other hand, through the vertical signal lines VSL2 and VSL3 adjacent to each other, signals read out from different color pixels (a red pixel and a green pixel, for example) are transmitted. At this time, to suppress color mixture, a shield line may be provided between the vertical signal lines VSL2 and VSL3.

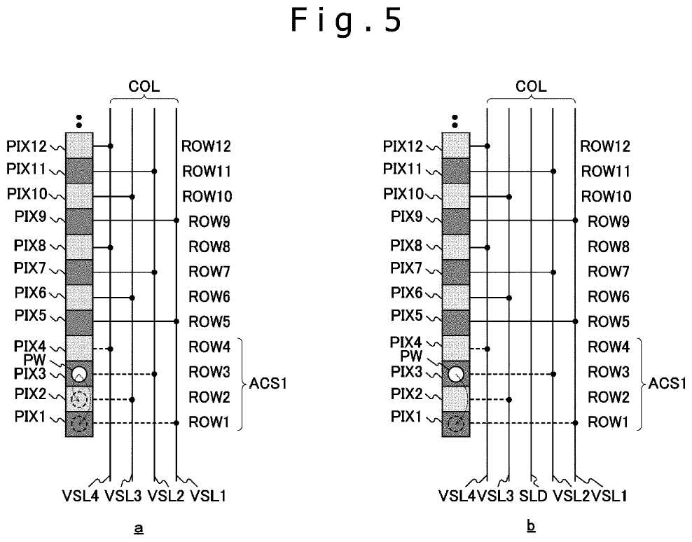

FIG. 5 is a diagram depicting an example of crosstalk of a defective pixel according to the first embodiment. Note that a in the drawing depicts an example of crosstalk of a defective pixel when there is no shield line between the vertical signal lines, and b in the drawing depicts an example of crosstalk of a defective pixel when there is a shield line between the vertical signal lines.

In a in the drawing, for example, it is assumed that a defect PW such as a white spot is present in the pixel PIX3. At this time, the vertical signal line VSL2 connected with the pixel PIX3 is adjacent to the vertical signal line VSL1 connected with the pixel PIX1 and the vertical signal line VSL3 connected with the pixel PIX2. Therefore, when signals are simultaneously read out from the pixels PIX1 to PIX4, the defect PW in the pixel PIX3 affects the signals read out from the pixels PIX1 and PIX2 as well.

Here, as depicted in b of the drawing, a shield line SLD is provided between the vertical signal lines VSL2 and VSL3 to suppress color mixture. At this time, even if signals are simultaneously read out from the pixels PIX1 to PIX4, the defect PW of the pixel PIX3 can be made not to affect the signal read out from the pixel PIX2.

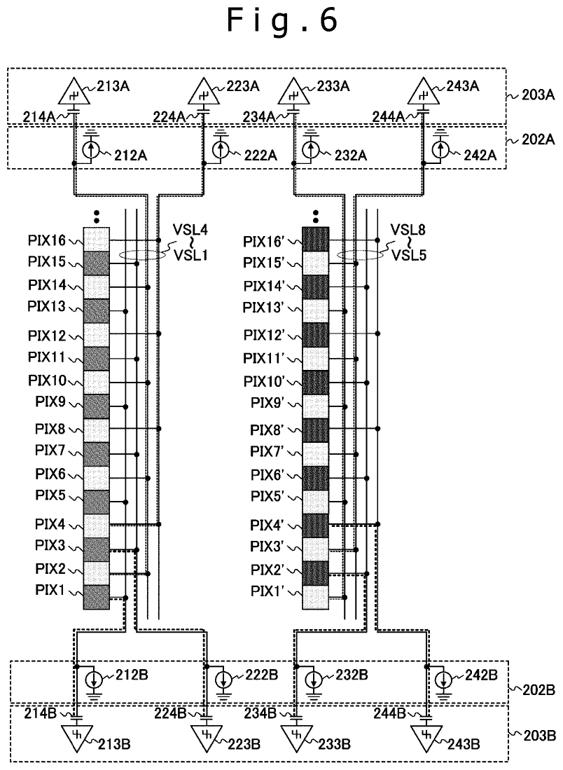

FIG. 6 is a block diagram depicting transmission paths of signals read out from pixels at the first timing according to the first embodiment. Note that, in the drawing, an example in which the pixels PIX form a Bayer array is depicted.

In the drawing, in the first column, pixels PIX1 to PIX16 are disposed in the column direction. In the second column, pixels PIX1′ to PIX16′ are disposed in the column direction. The pixels PIX1, PIX3, PIX5, PIX7, PIX9, PIX11, PIX13, and PIX15 can be red pixels. The pixels PIX2, PIX4, PIX6, PIX8, PIX10, PIX12, PIX14, PIX16, PIX1′, PIX3′, PIX5′, PIX7′, PIX9′, PIX11′, PIX13′, and PIX15′ can be green pixels. The pixels PIX2′, PIX4′, PIX6′, PIX8′, PIX10′, PIX12′, PIX14′, and PIX16′ can be blue pixels. In addition, vertical signal lines VSL1 to VSL4 are disposed in the first column, and vertical signal lines VSL5 to VSL8 are disposed in the second column.

The pixels PIX1, PIX5, PIX9, and PIX13 are connected to the vertical signal line VSL1, and the pixels PIX3, PIX7, PIX11, and PIX15 are connected to the vertical signal line VSL2. The pixels PIX2, PIX6, PIX10, and PIX14 are connected to the vertical signal line VSL3, and the pixels PIX4, PIX8, PIX12, and PIX16 are connected to the vertical signal line VSL4.

The pixels PIX1′, PIX5′, PIX9′, and PIX13′ are connected to the vertical signal line VSL5, and the pixels PIX3′, PIX7′, PIX11′, and PIX15′ are connected to the vertical signal line VSL6. The pixels PIX2′, PIX6′, PIX10′, and PIX14′ are connected to the vertical signal line VSL7, and the pixels PIX4′, PIX8′, PIX12′, and PIX16′ are connected to the vertical signal line VSL8.

The column readout circuit 113 is provided with constant current readout sections 202A and 202B. The constant current readout sections 202A and 202B form a source follower with each pixel PIX, and can read out a signal from each pixel PIX. The constant current readout sections 202A and 202B can be disposed on both sides of the vertical signal lines VSL1 to VSL8. At this time, the constant current readout section 202A can be disposed at one end portion of the vertical signal lines VSL1 to VSL8, and the constant current readout section 202B can be disposed at the other end portion of the vertical signal lines VSL1 to VSL8.

The constant current readout section 202A includes current sources 212A, 222A, 232A, and 242A. The current source 212A is connected to the vertical signal line VSL3, the current source 222A is connected to the vertical signal line VSL4, the current source 232A is connected to the vertical signal line VSL5, and the current source 242A is connected to the vertical signal line VSL6.

The constant current readout section 202B includes current sources 212B, 222B, 232B, and 242B. The current source 212B is connected to the vertical signal line VSL1, the current source 222B is connected to the vertical signal line VSL2, the current source 232B is connected to the vertical signal line VSL7, and the current source 242B is connected to the vertical signal line VSL8.

The column signal processing unit 114 includes column ADC sections 203A and 203B. The column ADC sections 203A and 203B can perform AD conversion on the signals read out from the pixels PIX in parallel on a per column basis. The column ADC sections 203A and 203B can be disposed on both sides of the vertical signal lines VSL1 to VSL8. At this time, the column ADC section 203A can be disposed at one end portion of the vertical signal lines VSL1 to VSL8, and the column ADC section 203B can be disposed at the other end portion of the vertical signal lines VSL1 to VSL8.

The column ADC section 203A includes comparators 213A, 223A, 233A, and 243A, and capacitors 214A, 224A, 234A, and 244A. The comparator 213A is connected to the vertical signal line VSL3 via the capacitor 214A, and the comparator 223A is connected to the vertical signal line VSL4 via the capacitor 224A. The comparator 233A is connected to the vertical signal line VSL5 via the capacitor 234A, and the comparator 243A is connected to the vertical signal line VSL6 via the capacitor 244A.

The column ADC section 203B includes comparators 213B, 223B, 233B, and 243B, and capacitors 214B, 224B, 234B, and 244B. The comparator 213B is connected to the vertical signal line VSL1 via the capacitor 214B, and the comparator 223B is connected to the vertical signal line VSL2 via the capacitor 224B. The comparator 233B is connected to the vertical signal line VSL7 via the capacitor 234B, and the comparator 243B is connected to the vertical signal line VSL8 via the capacitor 244B.

The comparators 213A, 223A, 233A, 243A, 213B, 223B, 233B, and 243B compare the signals respectively transmitted from the vertical signal lines VSL3, VSL4, VSL5, VSL6, VSL1, VSL2, VSL7, and VSL8 with a reference voltage. Then, the signals transmitted from the vertical signal lines VSL3, VSL4, VSL5, VSL6, VSL1, VSL2, VSL7, and VSL8 are AD-converted on the basis of a count value until the signals coincide with the reference voltage.

Here, in a first horizontal period, signals are simultaneously read out from the pixels PIX1 to PIX4 and PIX1′ to PIX4′. Then, signals read out from the pixels PIX1 to PIX4 and PIX1′ to PIX4′ are transmitted in the column direction via the vertical signal lines VSL3, VSL4, VSL5, VSL6, VSL1, VSL2, VSL7, and VSL8, respectively. At this time, the signals read out from the pixels PIX2, PIX4, PIX1′, and PIX3′ and the signals read out from the pixels PIX1, PIX3, PIX2′, and PIX4′ are transmitted in opposite directions. Then, the signals read out from the pixels PIX2, PIX4, PIX1′, and PIX3′ are transmitted to the column ADC section 203A, and the signals read out from the pixels PIX1, PIX3, PIX2′, and PIX4′ are transmitted to the column ADC section 203B.

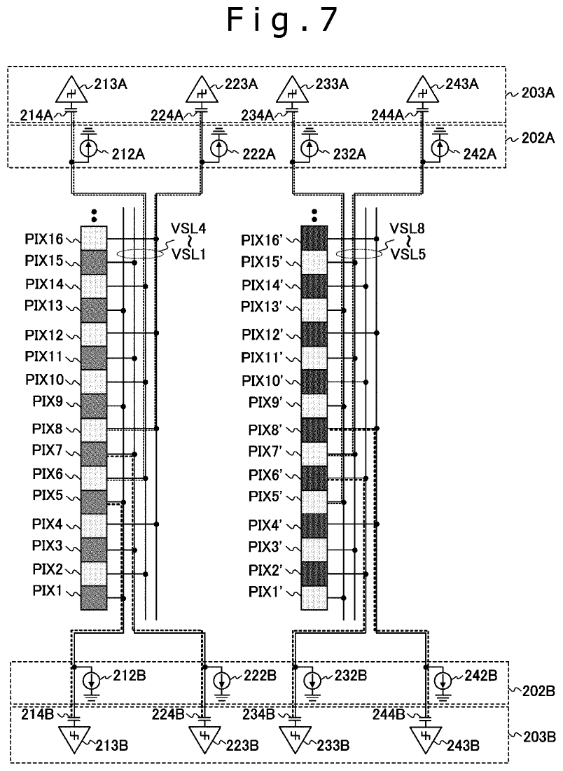

FIG. 7 is a block diagram depicting transmission paths of signals read out from pixels at the second timing according to the first embodiment.

In the drawing, in a second horizontal period, signals are simultaneously read out from the pixels PIX5 to PIX8 and PIX5′ to PIX8′. Then, signals read out from the pixels PIX5 to PIX8 and PIX5′ to PIX8′ are transmitted in the column direction via the vertical signal lines VSL3, VSL4, VSL5, VSL6, VSL1, VSL2, VSL7, and VSL8, respectively. At this time, the signals read out from the pixels PIX6, PIX8, PIX5′, and PIX7′ and the signals read out from the pixels PIX5, PIX7, PIX6′, and PIX8′ are transmitted in opposite directions. Then, the signals read out from the pixels PIX6, PIX8, PIX5′, and PIX7′ are transmitted to the column ADC section 203A, and the signals read out from the pixels PIX5, PIX7, PIX6′, and PIX8′ are transmitted to the column ADC section 203B.

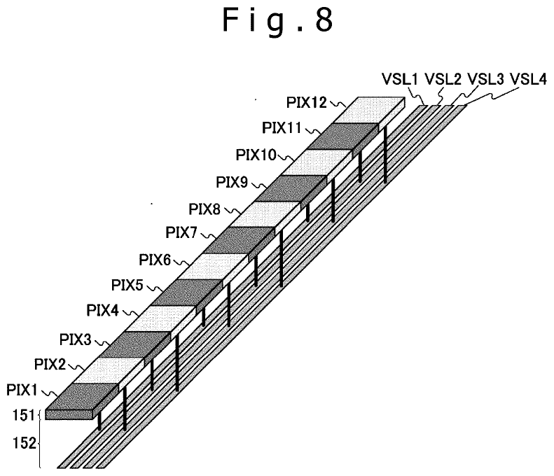

FIG. 8 is a perspective view depicting a layout example of pixels and vertical signal lines according to the first embodiment. Note that the drawing depicts an example of the layout of the pixels and the vertical signal lines of a back-illuminated image sensor.

In this drawing, the back-illuminated image sensor includes a semiconductor substrate 151 and a wiring layer 152. The wiring layer 152 is formed on the semiconductor substrate 151. The pixels PIX1 to PIX12 are formed on a back surface side of the semiconductor substrate 151. At this time, light is incident on each pixel PIX1 to PIX12 from the back surface side of the semiconductor substrate 151. The vertical signal lines VSL1 to VSL4 are formed in the wiring layer 152. The signals read out from the pixels PIX1 to PIX12 are transmitted via the vertical signal lines VSL1 to VSL4. Note that the vertical signal lines VSL1 to VSL4 may be formed in the same wiring layer, or any of the vertical signal lines VSL1 to VSL4 may be formed in a different wiring layer.

Thus, in the first embodiment described above, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL differ from each other. Accordingly, the pixels PIX1 and PIX2 of different colors adjacent to each other can be connected to the vertical signal lines VSL1 and VSL3 not adjacent to each other, and the pixels PIX3 and PIX4 of different colors adjacent to each other can be connected to the vertical signal lines VSL2 and VSL4 not adjacent to each other. This makes it possible to suppress color mixture of signals read out from the pixels PIX1 and PIX2 of different colors and suppress color mixture of signals read out from the pixels PIX3 and PIX4 of different colors.

However, the pixels PIX2 and PIX3 of different colors adjacent to each other are connected to the vertical signal lines VSL3 and VSL2 adjacent to each other. At this time, to suppress color mixture of signals read out from the pixels PIX2 and PIX3 of different colors, the shield line SLD may be provided between the vertical signal lines VSL2 and VSL3 as illustrated in b of FIG. 5.

Further, in the embodiment described above, an example in which the pixels PIX include different color pixels has been described, but the pixels PIX may include only same color pixels. At this time, the image generated by the imaging device is not necessarily limited to a color image, and may be a monochrome image, may be an infrared image, or may be a distance image.

### 2. Second Embodiment

In the first embodiment described above, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL differ from each other. In this second embodiment, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL coincide with each other.

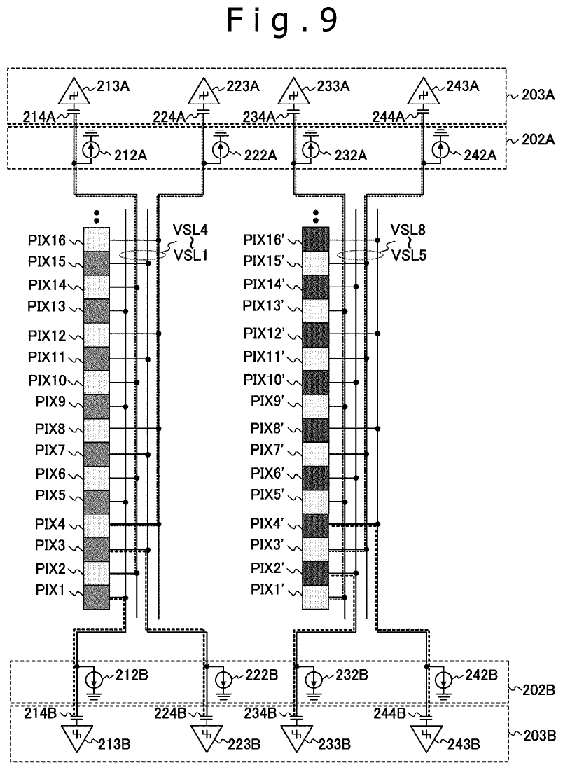

FIG. 9 is a block diagram depicting transmission paths of signals read out from pixels at the first timing according to the second embodiment. Note that, in the drawing, an example in which the pixels PIX form a Bayer array is depicted.

In the drawing, in this imaging device, the array order of the four vertical signal lines VSL1 to VSL4 and the array order of the pixels PIX1 to PIX16 provided in the first column coincide with each other. Further, the array order of the four vertical signal lines VSL5 to VSL8 and the array order of the pixels PIX1′ to PIX16′ provided in the second column coincide with each other. Other configurations of the imaging device of the second embodiment are similar to the configurations of the imaging device of the first embodiment described above.

At this time, the pixels PIX1, PIX5, PIX9, and PIX13 are connected to the vertical signal line VSL1, and the pixels PIX2, PIX6, PIX10, and PIX14 are connected to the vertical signal line VSL2. The pixels PIX3, PIX7, PIX11, and PIX15 are connected to the vertical signal line VSL3, and the pixels PIX4, PIX8, PIX12, and PIX16 are connected to the vertical signal line VSL4.

The pixels PIX1′, PIX5′, PIX9′, and PIX13′ are connected to the vertical signal line VSL5, and the pixels PIX2′, PIX6′, PIX10′, and PIX14′ are connected to the vertical signal line VSL6. The pixels PIX3′, PIX7′, PIX11′, and PIX15′ are connected to the vertical signal line VSL7, and the pixels PIX4′, PIX8′, PIX12′, and PIX16′ are connected to the vertical signal line VSL8.

The current source 212A is connected to the vertical signal line VSL2, the current source 222A is connected to the vertical signal line VSL4, the current source 232A is connected to the vertical signal line VSL5, and the current source 242A is connected to the vertical signal line VSL7.

The current source 212B is connected to the vertical signal line VSL1, the current source 222B is connected to the vertical signal line VSL3, the current source 232B is connected to the vertical signal line VSL6, and the current source 242B is connected to the vertical signal line VSL8.

The comparator 213A is connected to the vertical signal line VSL2 via the capacitor 214A, and the comparator 223A is connected to the vertical signal line VSL4 via the capacitor 224A. The comparator 233A is connected to the vertical signal line VSL5 via the capacitor 234A, and the comparator 243A is connected to the vertical signal line VSL7 via the capacitor 244A.

The comparator 213B is connected to the vertical signal line VSL1 via the capacitor 214B, and the comparator 223B is connected to the vertical signal line VSL3 via the capacitor 224B. The comparator 233B is connected to the vertical signal line VSL6 via the capacitor 234B, and the comparator 243B is connected to the vertical signal line VSL8 via the capacitor 244B.

Here, in the first horizontal period, signals are simultaneously read out from each of the pixels PIX1 to PIX4 and PIX1′ to PIX4′. Then, signals read out from the pixels PIX1 to PIX4 and PIX1′ to PIX4′ are transmitted in the column direction via the vertical signal lines VSL2, VSL4, VSL5, VSL7, VSL1, VSL3, VSL6, and VSL8, respectively. At this time, the signals read out from the pixels PIX2, PIX4, PIX1′, and PIX3′ and the signals read out from the pixels PIX1, PIX3, PIX2′, and PIX4′ are transmitted in opposite directions. Then, the signals read out from the pixels PIX2, PIX4, PIX1′, and PIX3′ are transmitted to the column ADC section 203A, and the signals read out from the pixels PIX1, PIX3, PIX2′, and PIX4′ are transmitted to the column ADC section 203B.

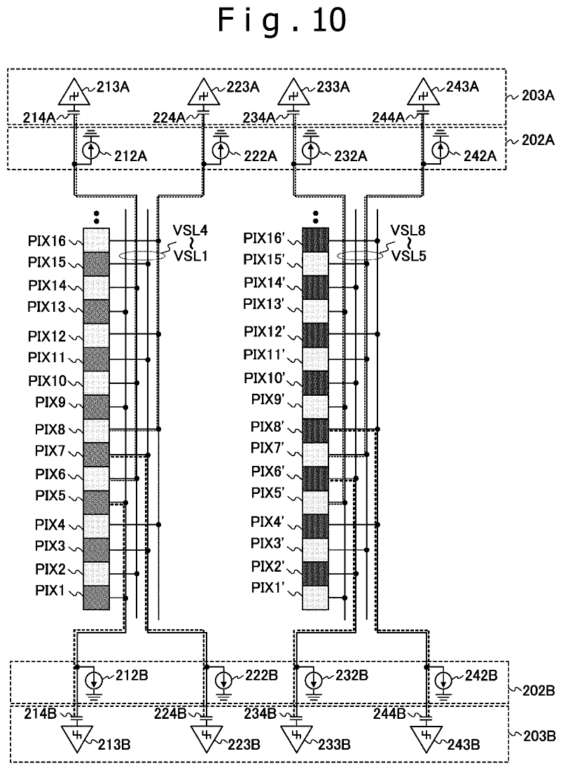

FIG. 10 is a block diagram depicting transmission paths of signals read out from pixels at the second timing according to the second embodiment.

In the drawing, in the second horizontal period, signals are simultaneously read out from each of the pixels PIX5 to PIX8 and PIX5′ to PIX8′. Then, signals read out from the pixels PIX5 to PIX8 and PIX5′ to PIX8′ are transmitted in the column direction via the vertical signal lines VSL2, VSL4, VSL5, VSL7, VSL1, VSL3, VSL6, and VSL8, respectively. At this time, the signals read out from the pixels PIX6, PIX8, PIX5′, and PIX7′ and the signals read out from the pixels PIX5, PIX7, PIX6′, and PIX8′ are transmitted in opposite directions. Then, the signals read out from the pixels PIX6, PIX8, PIX5′, and PIX7′ are transmitted to the column ADC section 203A, and the signals read out from the pixels PIX5, PIX7, PIX6′, and PIX8′ are transmitted to the column ADC section 203B.

Thus, in the second embodiment described above, the vertical signal lines and the pixels are connected such that the array order of the plurality of vertical signal lines and the array order of the pixels, in the column direction, provided in the column coincide with each other.

Furthermore, signals read out at the same timing from pixels belonging to the same column and in mutually different rows are transmitted in opposite directions. This makes it possible to dispose the column ADC sections 203A and 203B on both sides of the vertical signal lines VSL1 to VSL8, and improve a degree of freedom of a layout of the column ADC sections 203A and 203B.

### 3. Third Embodiment

In the first embodiment described above, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL differ from each other. In this third embodiment, the readout timing from each of the pixels PIX1 to PIX12 is set such that different color pixels are read out at mutually different timings in the column COL provided with the four vertical signal lines VSL1 to VSL4.

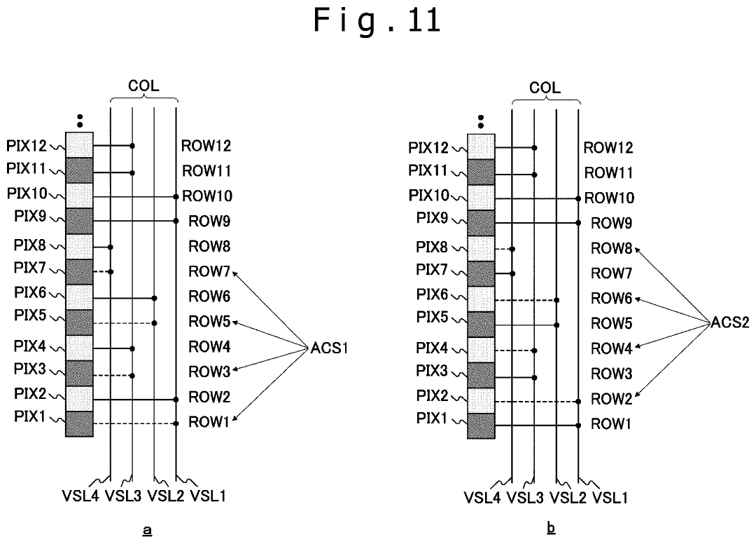

FIG. 11 is a diagram depicting an example of connection between pixels and vertical signal lines according to the third embodiment. Note that a in the drawing indicates a connection relationship between the pixels of four rows accessed at a first timing and the vertical signal lines, and b in the drawing indicates a connection relationship between the pixels of four rows accessed at a second timing and the vertical signal lines.

In the drawing, in this imaging device, the vertical signal lines VSL1 to VSL4 are connected to the pixels PIX such that the array order of the vertical signal lines VSL and the array order of the pixels PIX in each column COL differ from each other. Here, in each column COL, two different color pixels adjacent in the column direction are connected to the same vertical signal lines VSL1 to VSL4, respectively. Furthermore, from the two different color pixels respectively connected to the same vertical signal lines VSL1 to VSL4, the signals are read out at mutually different timings. Other configurations of the imaging device of the third embodiment are similar to the configurations of the imaging device of the first embodiment described above.

Here, the pixels PIX1, PIX2, PIX9, and PIX10 can be connected to the vertical signal line VSL1, and the pixels PIX5 and PIX6 can be connected to the vertical signal line VSL2.

The pixels PIX3, PIX4, PIX11, and PIX12 can be connected to the vertical signal line VSL3, and the pixels PIX7 and PIX8 can be connected to the vertical signal line VSL4. At this time, the two pixels PIX1 and PIX2 of different colors are connected to the same vertical signal line VSL1, and the two pixels PIX5 and PIX6 of different colors are connected to the same vertical signal line VSL2. The two pixels PIX3 and PIX4 of different colors are connected to the same vertical signal line VSL3, and the two pixels PIX7 and PIX8 of different colors are connected to the same vertical signal line VSL4.

In the signal readout, at the first timing, as depicted in a of the drawing, the access ACS1 is implemented in the pixels PIX1, PIX3, PIX5, and PIX7 belonging to the respective rows ROW1, ROW3, ROW5, and ROW7. At this time, the signals read out from the pixels PIX1, PIX3, PIX5, and PIX7 are simultaneously transmitted in the column direction via the vertical signal lines VSL1, VSL3, VSL2, and VSL4, respectively. Further, at the second timing, as illustrated in b of the drawing, the access ACS2 is implemented in the pixels PIX2, PIX4, PIX6, and PIX8 belonging to the respective rows ROW2, ROW4, ROW6, and ROW8. At this time, the signals read out from the pixels PIX2, PIX4, PIX6, and PIX8 are simultaneously transmitted in the column direction via the vertical signal lines VSL1, VSL3, VSL2, and VSL4, respectively.

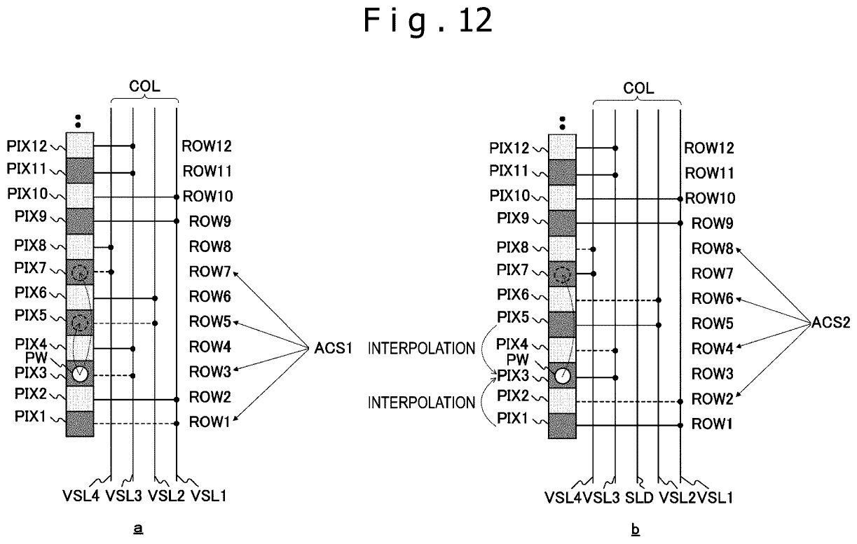

FIG. 12 is a diagram depicting an example of crosstalk of a defective pixel according to the third embodiment. Note that a in the drawing depicts an example of crosstalk of a defective pixel when there is no shield line between the vertical signal lines, and b in the drawing depicts an example of crosstalk of a defective pixel when there is a shield line between the vertical signal lines.

In a in the drawing, for example, it is assumed that the defect PW such as a white spot is present in the pixel PIX3. At this time, the vertical signal line VSL3 connected with the pixel PIX3 is adjacent to the vertical signal line VSL2 connected with the pixel PIX5 and the vertical signal line VSL4 connected with the pixel PIX7. Therefore, when signals are simultaneously read out from the pixels PIX1, PIX3, PIX5, and PIX7, the defect PW of the pixel PIX3 affects the signals read out from the pixels PIX5 and PIX7 as well. However, in the third embodiment, even if signals are simultaneously read out from the pixels PIX1, PIX3, PIX5, and PIX7, color mixture does not occur because the pixels PIX1, PIX3, PIX5, and PIX7 are of the same color.

Here, as depicted in b of the drawing, the shield line SLD is provided between the vertical signal lines VSL2 and VSL3. At this time, even if signals are simultaneously read out from the pixels PIX1, PIX3, PIX5, and PIX7, the defect PW of the pixel PIX3 can be made not to affect the signal read out from the pixel PIX5. Therefore, by interpolating the signal of the pixel PIX3 on the basis of the signals of the pixels PIX1 and PIX5 adjacent to the pixel PIX3 between the same color pixels, it is possible to correct the effect of the defect PW of the pixel PIX3.

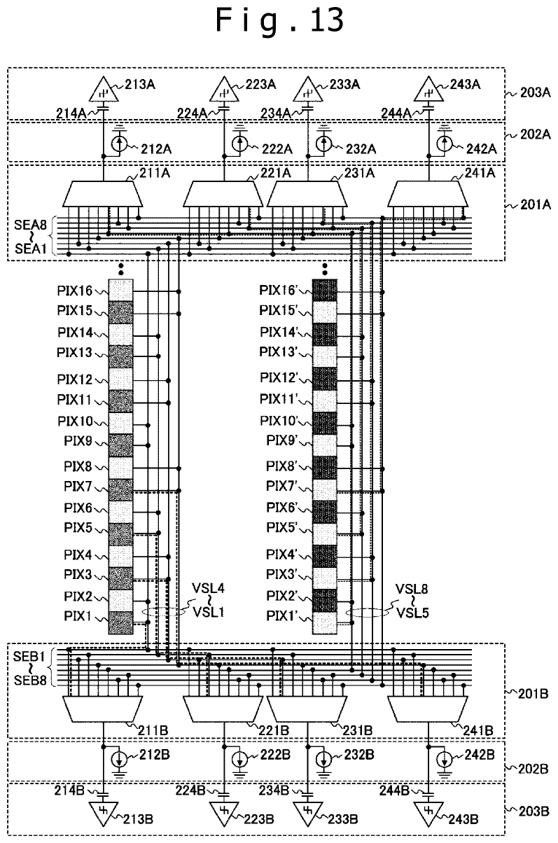

FIG. 13 is a block diagram depicting transmission paths of signals read out from pixels at the first timing according to the third embodiment. Note that, in the drawing, an example in which the pixels PIX form a Bayer array is depicted.

In the drawing, this imaging device is obtained by adding switching sections 201A and 201B to the imaging device of the first embodiment described above. Furthermore, one end of each of the vertical signal lines VSL1 to VSL8 is connected to the constant current readout section 202A and the column ADC section 203A via the switching section 201A. The other end of each of the vertical signal lines VSL1 to VSL8 is connected to the constant current readout section 202B and the column ADC section 203B via the switching section 201B. Other configurations of the imaging device of the third embodiment are similar to the configurations of the imaging device of the first embodiment described above.

Each of the switching sections 201A and 201B alternately switches a connection destination of each of the vertical signal lines VSL1 to VSL8 for each horizontal period. For example, the switching section 201A connects the vertical signal lines VSL5 to VSL8 to the constant current readout section 202A and the column ADC section 203A in the first horizontal period. Further, the switching section 201A connects the vertical signal lines VSL1 to VSL4 to the constant current readout section 202A and the column ADC section 203A in the second horizontal period. The switching section 201B connects the vertical signal lines VSL1 to VSL4 to the constant current readout section 202B and the column ADC section 203B in the first horizontal period. Further, the switching section 201B connects the vertical signal lines VSL5 to VSL8 to the constant current readout section 202B and the column ADC section 203B in the second horizontal period.

The switching sections 201A and 201B can be disposed on both sides of the vertical signal lines VSL1 to VSL8. At this time, the switching section 201A can be disposed at one end portion of the vertical signal lines VSL1 to VSL8, and the switching section 201B can be disposed at the other end portion of the vertical signal lines VSL1 to VSL8.

The switching section 201A includes multiplexers 211A to 241A and transmission lines SEA1 to SEA8. The transmission lines SEA1 to SEA8 are connected to the vertical signal lines VSL1 to VSL8, respectively. Outputs of the multiplexers 211A to 241A are connected to the current sources 212A, 222A, 232A, and 242A, respectively. Further, the outputs of the multiplexers 211A to 241A are connected to the comparators 213A, 223A, 233A, and 243A via the capacitors 214A, 224A, 234A, and 244A, respectively. The multiplexers 211A to 241A select the vertical signal lines VSL5 to VSL8, respectively, in the first horizontal period, and select the vertical signal lines VSL1 to VSL4, respectively, in the second horizontal period.

The switching section 201B includes multiplexers 211B to 241B and transmission lines SEB1 to SEB8. The transmission lines SEBA1 to SEBA8 are connected to the vertical signal lines VSL1 to VSL8, respectively. Outputs of the multiplexers 211B to 241B are connected to the current sources 212B, 222B, 232B, and 242B, respectively. The outputs of the multiplexers 211B to 241B are connected to the comparators 213B, 223B, 233B, and 243B via the capacitors 214B, 224B, 234B, and 244B, respectively. The multiplexers 211B to 241B select the vertical signal lines VSL1 to VSL4, respectively, in the first horizontal period, and select the vertical signal lines VSL5 to VSL8, respectively, in the second horizontal period.

Here, in the first horizontal period, signals are simultaneously read out from the pixels PIX1, PIX3, PIX5, PIX7, PIX1′, PIX3′, PIX5′, and PIX7′. Then, signals read out from the pixels PIX1, PIX3, PIX5, PIX7, PIX1′, PIX3′, PIX5′, and PIX7′ are transmitted in the column direction via the vertical signal lines VSL4, VSL2, VSL3, VSL1, VSL8, VSL6, VSL7, and VSL5, respectively. At this time, the signals read out from the pixels PIX1, PIX3, PIX5, and PIX7 and the signals read out from the pixels PIX1′, PIX3′, PIX5′, and PIX7′ are transmitted in opposite directions. Then, the signals read out from the pixels PIX1, PIX3, PIX5, and PIX7 are transmitted to the column ADC section 203B, and the signals read out from the pixels PIX1′, PIX3′, PIX5′, and PIX7′ are transmitted to the column ADC section 203A.

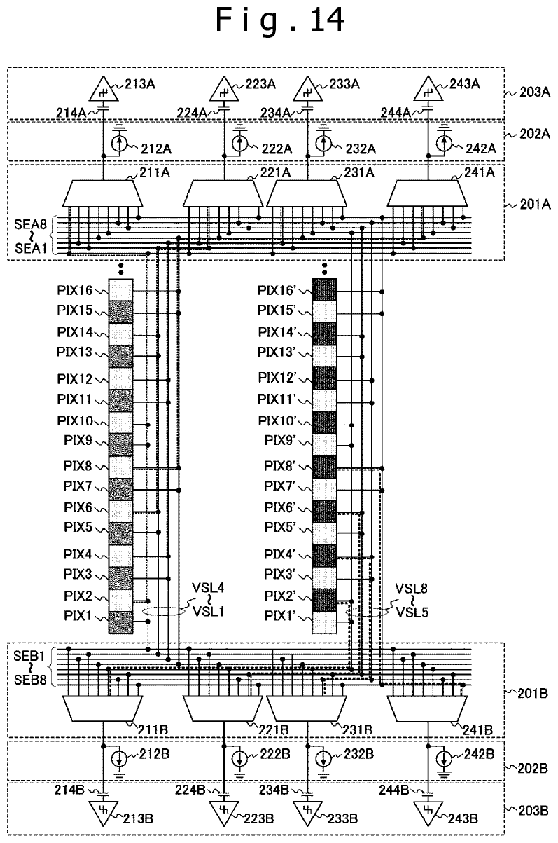

FIG. 14 is a block diagram depicting transmission paths of signals read out from pixels at the second timing according to the third embodiment.

In this drawing, in the second horizontal period, signals are simultaneously read out from the pixels PIX2, PIX4, PIX6, PIX8, PIX2′, PIX4′, PIX6′, and PIX8′. Then, signals read out from the pixels PIX2, PIX4, PIX6, PIX8, PIX2′, PIX4′, PIX6′, and PIX8′ are transmitted in the column direction via the vertical signal lines VSL4, VSL2, VSL3, VSL1, VSL8, VSL6, VSL7, and VSL5, respectively. At this time, the signals read out from the pixels PIX2, PIX4, PIX6, and PIX8 and the signals read out from the pixels PIX2′, PIX4′, PIX6′, and PIX8′ are transmitted in opposite directions. Then, the signals read out from the pixels PIX2, PIX4, PIX6, and PIX8 are transmitted to the column ADC section 203A, and the signals read out from the pixels PIX2′, PIX4′, PIX6′, and PIX8′ are transmitted to the column ADC section 203B.

Thus, in the third embodiment described above, the readout timings from the pixels PIX1 to PIX16 and from the pixels PIX1′ to PIX16′ are set such that different color pixels are read out at mutually different timings in each column. This makes it possible to prevent transmission of signals read out from the different color pixels via the vertical signal lines adjacent to each other, and suppress the color mixture of the signals read out from the different color pixels.

### 4. Fourth Embodiment

In the first embodiment described above, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL differ from each other. In this fourth embodiment, the vertical signal lines and the pixels are connected such that an array order of six vertical signal lines and an array order of the pixels provided in the column COL differ from each other.

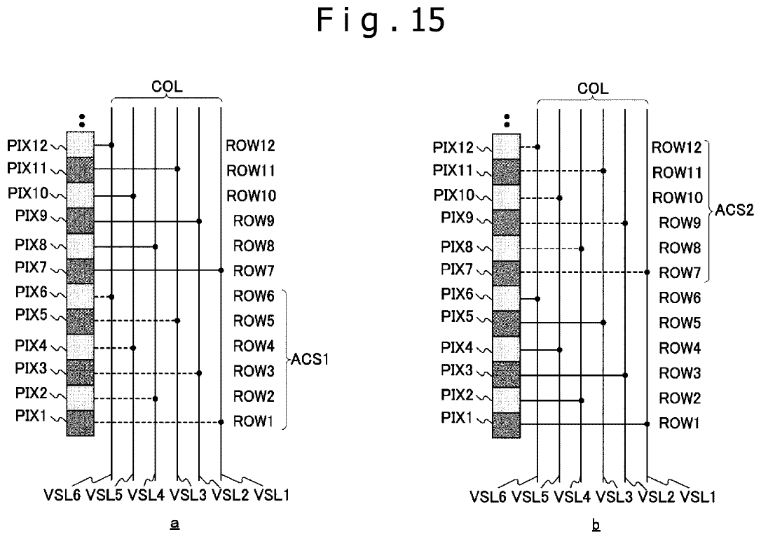

FIG. 15 is a diagram depicting an example of connection between pixels and vertical signal lines according to the fourth embodiment. Note that a in the drawing indicates a connection relationship between the pixels of six rows accessed at the first timing and the vertical signal lines, and b in the drawing indicates a connection relationship between the pixels of six rows accessed at the second timing and the vertical signal lines.

In the drawing, this imaging device includes the six vertical signal lines VSL1 to VSL6 in the column COL. At this time, the array order of the six vertical signal lines VSL1 to VSL6 and the array order of the pixels PIX1 to PIX12 provided in the column COL differ from each other. Other configurations of the imaging device of the fourth embodiment are similar to the configurations of the imaging device of the first embodiment described above.

Here, the pixels PIX1 and PIX7 can be connected to the vertical signal line VSL1, and the pixels PIX2 and PIX8 can be connected to the vertical signal line VSL4. The pixels PIX3 and PIX9 can be connected to the vertical signal line VSL2, and the pixels PIX4 and PX10 can be connected to the vertical signal line VSL5. The pixels PIX5 and PIX11 can be connected to the vertical signal line VSL3, and the pixels PIX6 and PX12 can be connected to the vertical signal line VSL6. At this time, the pixels PIX1, PIX3, and PIX5 of the same color are connected to the vertical signal lines VSL1 to VSL3 adjacent to each other. The pixels PIX7, PIX9, and PIX11 of the same color are connected to the vertical signal lines VSL1 to VSL3 adjacent to each other. Further, the pixels PIX2, PIX4, and PIX6 of the same color are connected to the vertical signal lines VSL4 to VSL6 adjacent to each other. The pixels PIX8, PIX10, and PIX12 of the same color are connected to the vertical signal lines VSL4 to VSL6 adjacent to each other.

In the signal readout, at the first timing, as depicted in a of the drawing, the access ACS1 is implemented in the pixels PIX1 to PIX6 belonging to the respective rows ROW1 to ROW6. At this time, the signals read out from the pixels PIX1 to PIX6 are simultaneously transmitted in the column direction via the vertical signal lines VSL1, VSL4, VSL2, VSL5, VSL3, and VSL6, respectively. Further, at the second timing, as illustrated in b of the drawing, the access ACS2 is implemented in the pixels PIX7 to PIX12 belonging to the respective rows ROW7 to ROW12. At this time, the signals read out from the pixels PIX7 to PIX12 are simultaneously transmitted in the column direction via the vertical signal lines VSL1, VSL4, VSL2, VSL5, VSL3, and VSL6, respectively.

Here, through the vertical signal lines VSL1 to VSL3 adjacent to each other, signals read out from pixels of the same color (red pixels, for example) are transmitted, making it possible to suppress color mixture. Further, through the vertical signal lines VSL4 to VSL6 adjacent to each other, signals read out from pixels of the same color (green pixels, for example) are transmitted, making it possible to suppress color mixture. On the other hand, through the vertical signal lines VSL3 and VSL4 adjacent to each other, signals read out from different color pixels (a red pixel and a green pixel, for example) are transmitted. At this time, to suppress color mixture, a shield line may be provided between the vertical signal lines VSL3 and VSL4.

Thus, in the fourth embodiment described above, the vertical signal lines VSL1 to VSL6 and the pixels IX1 to PIX12 are connected such that the array order of the six vertical signal lines VSL1 to VSL6 and the array order of the pixels PIX1 to PIX12 provided in the column COL differ from each other. Accordingly, the pixels PIX1 and PIX2 of different colors adjacent to each other can be connected to the vertical signal lines VSL1 and VSL4 not adjacent to each other. Further, the pixels PIX3 and PIX4 of different colors adjacent to each other can be connected to the vertical signal lines VSL2 and VSL5 not adjacent to each other. Furthermore, the pixels PIX5 and PIX6 of different colors adjacent to each other can be connected to the vertical signal lines VSL3 and VSL6 not adjacent to each other. This makes it possible to suppress color mixture of signals read out from the pixels PIX1 and PIX2 of different colors, suppress color mixture of signals read out from the pixels PIX3 and PIX4 of different colors, and suppress color mixture of signals read out from the pixels PIX5 and PIX6 of different colors.

### 5. Fifth Embodiment

In the fourth embodiment described above, the vertical signal lines VSL1 to VSL6 and the pixels IX1 to PIX12 are connected such that the array order of the six vertical signal lines VSL1 to VSL6 and the array order of the pixels PIX1 to PIX12 provided in the column COL differ from each other. In this fifth embodiment, the readout timing from each of the pixels PIX1 to PIX12 is set such that different color pixels are read out at mutually different timings in the column COL provided with the six vertical signal lines VSL1 to VSL6.

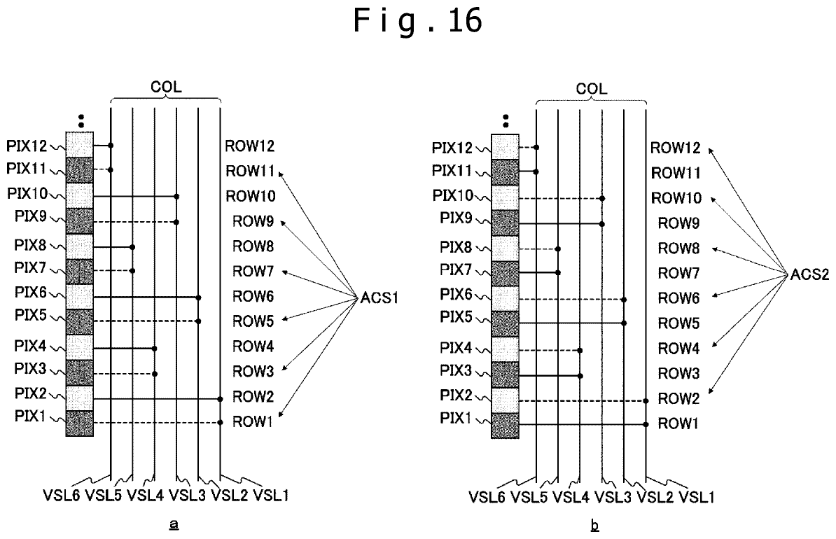

FIG. 16 is a diagram depicting an example of connection between pixels and vertical signal lines according to the fifth embodiment. Note that a in the drawing indicates a connection relationship between the pixels of six rows accessed at the first timing and the vertical signal lines, and b in the drawing indicates a connection relationship between the pixels of six rows accessed at the second timing and the vertical signal lines.

In the drawing, in this imaging device, the vertical signal lines VSL1 to VSL6 are connected to the pixels PIX such that the array order of the vertical signal lines VSL and the array order of the pixels PIX in each column COL differ from each other. Here, in each column COL, two different color pixels adjacent in the column direction are connected to the same vertical signal lines VSL1 to VSL6, respectively. Furthermore, from the two different color pixels respectively connected to the same vertical signal lines VSL1 to VSL6, the signals are read out at mutually different timings. Other configurations of the imaging device of the sixth embodiment are similar to the configurations of the imaging device of the fifth embodiment described above.

Here, the pixels PIX1 and PIX2 can be connected to the vertical signal line VSL1, and the pixels PIX5 and PIX6 can be connected to the vertical signal line VSL2. The pixels PIX9 and PIX10 can be connected to the vertical signal line VSL3, and the pixels PIX3 and PIX4 can be connected to the vertical signal line VSL4. The pixels PIX7 and PIX8 can be connected to the vertical signal line VSL5, and the pixels PIX11 and PIX12 can be connected to the vertical signal line VSL6. At this time, the two pixels PIX1 and PIX2 of different colors are connected to the same vertical signal line VSL1, and the two pixels PIX5 and PIX6 of different colors are connected to the same vertical signal line VSL2. The two pixels PIX9 and PIX10 of different colors are connected to the same vertical signal line VSL3, and the two pixels PIX3 and PIX4 of different colors are connected to the same vertical signal line VSL4. The two pixels PIX7 and PIX8 of different colors are connected to the same vertical signal line VSL5, and the two pixels PIX11 and PIX12 of different colors are connected to the same vertical signal line VSL6.

In the signal readout, at the first timing, as illustrated in a of the drawing, the access ACS1 is implemented in the pixels PIX1, PIX3, PIX5, PIX7, PIX9, and PIX11 belonging to the respective rows ROW1, ROW3, ROW5, ROW7, ROW9, and ROW11. At this time, the signals read out from the pixels PIX1, PIX3, PIX5, PIX7, PIX9, and PIX11 are simultaneously transmitted in the column direction via the vertical signal lines VSL1, VSL4, VSL2, VSL5, VSL3, and VSL6, respectively. Further, at the second timing, as illustrated in b of the drawing, the access ACS2 is implemented in the pixels PIX2, PIX4, PIX6, PIX8, PIX10, and PIX12 belonging to the respective rows ROW2, ROW4, ROW6, ROW8, ROW10, and ROW12. At this time, the signals read out from the pixels PIX2, PIX4, PIX6, PIX8, PIX10, and PIX12 are simultaneously transmitted in the column direction via the vertical signal lines VSL1, VSL4, VSL2, VSL5, VSL3, and VSL6, respectively.

### 6. Sixth Embodiment

In the first embodiment described above, the pixels PIX2 and PIX3 of different colors are connected to the vertical signal lines VSL3 and VSL2 adjacent to each other. In this sixth embodiment, a shield line connected to a ground potential is disposed between the vertical signal lines VSL3 and VSL2 connected to the pixels PIX2 and PIX3 of different colors.

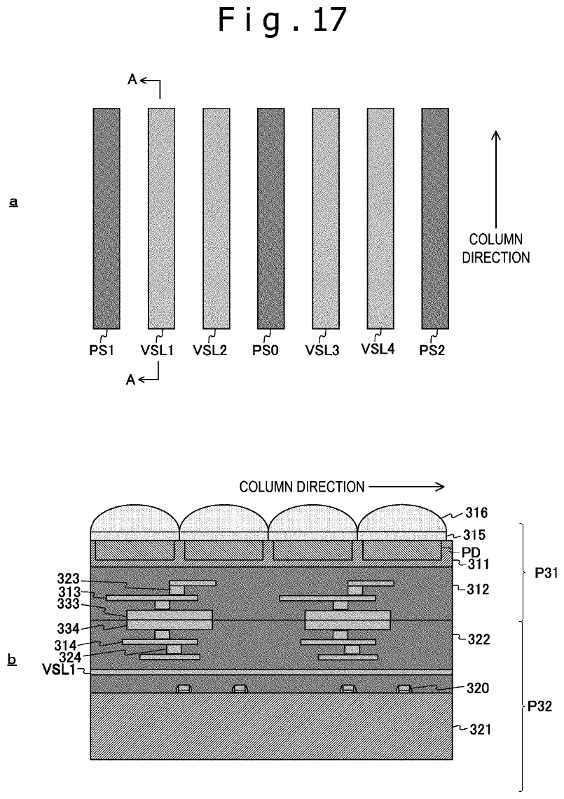

FIG. 17 is a diagram depicting a configuration example of a pixel array section provided in a solid-state imaging device according to the sixth embodiment. Note that a in the drawing is a plan view depicting an example of the layout of the vertical signal lines. b in the drawing is a cross-sectional view illustrating a configuration example of a wiring layer of the pixel array section. Further, b in the drawing depicts a configuration taken at a position of line A-A in a in the drawing. Further, the drawing depicts an example of a front-illuminated solid-state imaging device for four pixels.

In a of the drawing, a shield line PS0 is disposed between the vertical signal lines VSL3 and VSL2. The shield line PS0 can be disposed in parallel with the vertical signal lines VSL3 and VSL2. Further, a shield line PS1 can be disposed in parallel with the vertical signal line VSL1, and a shield line PS2 can be disposed in parallel with the vertical signal line VSL4.

The shield lines PS1 and PS2 can be used for shielding the vertical signal lines of mutually different columns. The shield lines PS0 to PS2 can be connected to the ground potential.

At this time, as depicted in b of the drawing, the solid-state imaging device can be provided with semiconductor chips P31 and P32. The semiconductor chip P31 is layered on the semiconductor chip P32.

The semiconductor chip P31 includes a semiconductor substrate 311. A photodiode PD is formed in the semiconductor substrate 311 for each pixel PIX. The photodiode PD can be disposed on a back surface side of the semiconductor substrate 311. At this time, light can be incident on the photodiode PD from the back surface side of the semiconductor substrate 311. A material of the semiconductor substrate 311 may be Si, may be InGaAs, or may be InP.

A wiring layer 312 is formed on the semiconductor substrate 311. The wiring layer 312 is provided with a wiring line 313 and a pad electrode 333 embedded in an insulating layer. The wiring layer 312 is provided with a via 323 used for interlayer connection. The pad electrode 333 can be used for direct bonding between the chips P31 and P32.

A color filter 315 is formed on the back surface of the semiconductor substrate 311 for each pixel PIX. A microlens 316 is formed on the color filter 315 for each pixel PIX. As a material of the color filter 315 and the microlens 316, a transparent resin such as acrylic or polycarbonate can be used, for example. A pigment may be added to the color filter 315 for coloring. The color filters 315 may form, for example, a Bayer array or a quad Bayer array.

The color filter 315 may include an RGB filter, may include a complementary color filter, or may include a white filter.

The semiconductor chip P32 includes a semiconductor substrate 321. A material of the semiconductor substrate 321 may be Si, may be GaAs, may be GaN, or may be SiC. On the semiconductor chip P32, a logic circuit may be formed, a memory may be formed, a processor may be formed, a signal processing circuit may be formed, or an interface circuit may be formed. At this time, a gate electrode 320 and a wiring layer 322 are formed on the semiconductor substrate 321. The gate electrode 320 is formed on the semiconductor substrate 321 with a gate insulating film interposed therebetween. As a material of the gate electrode 320, polycrystalline silicon into which impurities are introduced can be used, for example.

The gate electrode 320 can be used for a pixel transistor. The pixel transistor includes the transfer transistor 122, the reset transistor 123, the amplification transistor 124, and the selection transistor 125 in FIG. 3.

The wiring layer 322 is formed on the gate electrode 320. The wiring layer 322 is provided with a wiring line 314 and a pad electrode 334 embedded in an insulating layer. Further, the wiring layer 322 is provided with a via 324 used for interlayer connection. The pad electrode 334 can be used for direct bonding between the chips P31 and P32. Hybrid bonding can be used for direct bonding between the chips P31 and P32. At this time, the pad electrodes 333 and 334 are disposed at positions facing each other. Then, the pad electrodes 333 and 334 can be bonded to each other on the basis of metal bonding such as Cu—Cu bonding. Further, in the wiring layer 322, the vertical signal lines VSL1 to VSL4 and the shield lines PS0 to PS2 are disposed in parallel. Note that other wiring lines (for example, wiring lines for control lines of pixel transistors, or the like) may be formed in the same layer as that of the vertical signal lines VSL1 to VSL4 and the shield lines PS0 to PS2.

Silicon oxide films may be used for the insulating layers of the wiring layers 312 and 322, for example. As materials of the wiring lines 313 and 314, the vias 323 and 324, the pad electrodes 333 and 334, the vertical signal lines VSL1 to VSL4, and the shield lines PS0 to PS2, metals such as Cu, for example, can be used.

Thus, in the sixth embodiment described above, the shield line PS0 connected to the ground potential is disposed between the vertical signal lines VSL3 and VSL2 connected to the pixels PIX2 and PIX3 of different colors. This makes it possible to suppress color mixture of signals read out from the pixels PIX2 and PIX3 of different colors in the same column. At this time, by connecting the shield lines PS0 to PS2 to the ground potential, it is possible to stabilize shielding properties of the shield lines PS0 to PS2.

### 7. Seventh Embodiment

In the sixth embodiment described above, the shield line PS0 disposed between the vertical signal lines VSL3 and VSL2 connected to the pixels PIX2 and PIX3 of different colors is connected to the ground potential. In this seventh embodiment, the shield line PS0 disposed between the vertical signal lines VSL3 and VSL2 connected to the pixels PIX2 and PIX3 of different colors is connected to a power supply potential.

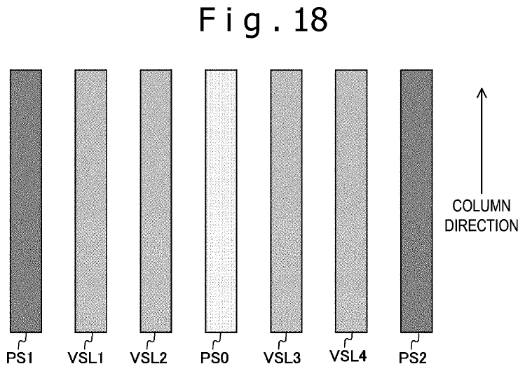

FIG. 18 is a diagram depicting a configuration example of a pixel array section provided in a solid-state imaging device according to the seventh embodiment. Note that, in the drawing, a configuration example for four pixels is depicted.

In the drawing, the shield line PS0 disposed between the vertical signal lines VSL3 and VSL2 is connected to the power supply potential. Other configurations of the imaging device of the seventh embodiment are similar to the configurations of the imaging device of the sixth embodiment described above. At this time, by connecting the shield line PS0 to the power supply potential, it is possible to make a connection to the power supply potential in the wiring layer including the vertical signal lines VSL1 to VSL4.

Thus, in the seventh embodiment described above, the shield line PS0 disposed between the vertical signal lines VSL3 and VSL2 connected to the pixels PIX2 and PIX3 of different colors is connected to the power supply potential. This makes it possible to secure the shielding properties between the vertical signal lines VSL3 and VSL2 without connecting the shield line PS0 to the ground potential, and alleviate restrictions on a layout of the power supply potential and the ground potential.

### 8. Eighth Embodiment

In the seventh embodiment described above, the shield line PS0 disposed between the vertical signal lines VSL3 and VSL2 connected to the pixels PIX2 and PIX3 of different colors is connected to the power supply potential. In this eighth embodiment, the shield line is divided between the vertical signal lines VSL3 and VSL2 such that a portion connected to the power supply potential is interposed between portions connected to the ground potential.

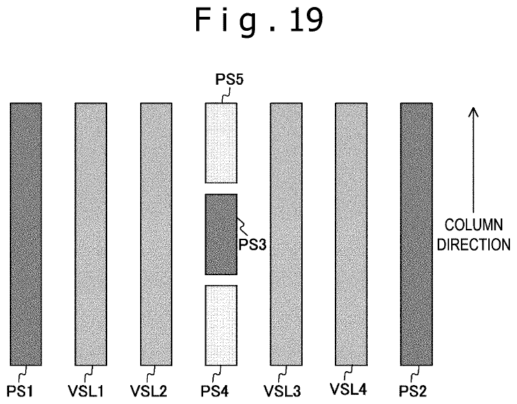

FIG. 19 is a diagram depicting a configuration example of a pixel array section provided in a solid-state imaging device according to the eighth embodiment. Note that, in the drawing, a configuration example for four pixels is depicted.

In the drawing, shield lines PS3 to PS5 are disposed between the vertical signal lines VSL3 and VSL2. The shield line PS3 is connected to the power supply potential, and the shield lines PS4 and PS5 are connected to the ground potential. At this time, the shield line PS3 is interposed between the shield lines PS4 and PS5 in the column direction. This makes it possible to make the connection to the power supply potential in the wiring layer including the vertical signal lines VSL1 to VSL4, and to make it difficult for power supply fluctuation to be transmitted to the vertical signal lines VSL3 and VSL2, thereby suppressing deterioration of a power supply rejection ratio (PSRR).

Thus, in the eighth embodiment described above, the shield lines PS3 to PS5 are disposed between the vertical signal lines VSL3 and VSL2 such that the shield line PS3 connected to the power supply potential is interposed between the shield lines PS4 and PS5. This makes it possible to stabilize the shielding properties between the vertical signal lines VSL3 and VSL2 while alleviating restrictions on the layout of the ground potential.

### 9. Ninth Embodiment

In the first embodiment described above, the imaging device is provided with pixels having a fixed conversion efficiency. In this ninth embodiment, the imaging device is provided with pixels having a switchable conversion efficiency.

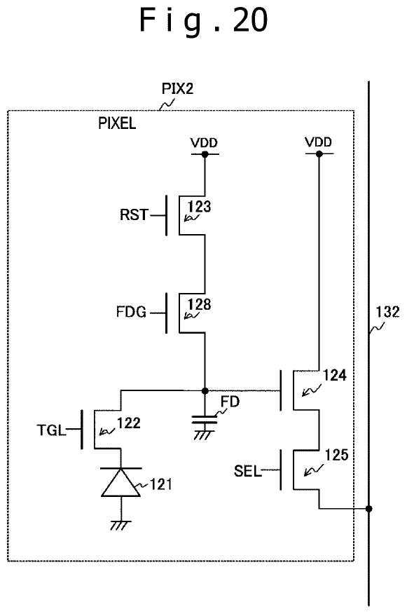

FIG. 20 is a diagram depicting a configuration example of a pixel according to the ninth embodiment.

In the drawing, the imaging device includes a pixel PIX2 instead of the pixel PIX of the first embodiment described above. Other configurations of the imaging device of the ninth embodiment are similar to the configurations of the imaging device of the first embodiment described above.

The pixel PIX2 is obtained by adding a switching transistor 128 to the pixel PIX of the first embodiment described above. Other configurations of the pixel PIX2 of the ninth embodiment are similar to the configurations of the pixel PIX of the first embodiment described above.

The switching transistor 128 switches the conversion efficiency of the amplification transistor 124. The switching transistor 128 is connected between the floating diffusion FD and the reset transistor 123. A switching signal FDG is applied to a gate of the switching transistor 128.

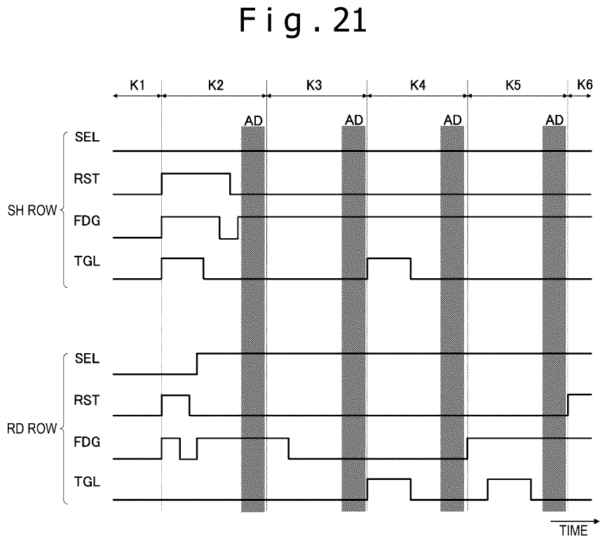

FIG. 21 is a timing chart depicting waveforms of respective sections during readout from the pixel according to the ninth embodiment. Note that an SH row indicates a shutter row, and an RD row indicates a read row. The SH rows are implemented, and then the RD rows are implemented. At this time, the SH rows can set the reference for the start of accumulation of the RD rows.

In the drawing, in the SH rows, the selection signal SEL is set to a low level, and the selection transistor 125 is turned off. In a non-selection period K1, a transfer signal TGL, a reset signal RST, and the switching signal FDG are maintained at the low level. Then, after the non-selection period K1 has elapsed, a low-efficiency P-phase readout K2 is implemented. At this time, the transfer signal TGL, the reset signal RST, and the switching signal FDG rise, charges of the photodiode 121 and the floating diffusion FD are discharged, and the conversion efficiency in the amplification transistor 124 is lowered.

Subsequently, in the low-efficiency P-phase readout K2, the transfer signal TGL falls, and subsequently the switching signal FDG falls and the reset signal RST falls. Then, the switching signal FDG rises again, and subsequently the AD conversion processing is implemented. Here, by causing the switching signal FDG to fall once before the reset signal RST falls, it is possible to couple the floating diffusion FD to the switching transistor 128. This makes it possible to boost a potential of the floating diffusion FD and readily transfer the charge from the photodiode 121.

Next, a high-efficiency P-phase readout K3 is implemented. At this time, the AD conversion processing is implemented while the transfer signal TGL, the reset signal RST, and the switching signal FDG are maintained at levels similar to those during the low-efficiency P-phase readout K2.

Next, a high-efficiency D-phase readout K4 is implemented. At this time, the transfer signal TGL rises, and the charge of the photodiode 121 is discharged. Then, the transfer signal TGL falls, and subsequently the AD conversion processing is implemented. Here, in the high-efficiency D-phase readout K4, the reset signal RST is set to the low level. Therefore, the floating diffusion FD is in a floating state, making it possible to couple the floating diffusion FD to the transfer transistor 122. This makes it possible to boost the potential of the floating diffusion FD and readily extract the charge from the photodiode 121.

Next, a low-efficiency D-phase readout K5 is implemented. At this time, the AD conversion processing is implemented while the level of the reset signal RST is maintained, and subsequently the period transitions to a non-selection period K6.

In the RD rows, in the non-selection period K1, the selection signal SEL, the transfer signal TGL, the reset signal RST, and the switching signal FDG are maintained at the low level. Then, after the non-selection period K1 has elapsed, the low-efficiency P-phase readout K2 is implemented. At this time, the reset signal RST and the switching signal FDG rise, the charge of the floating diffusion FD is discharged, and the conversion efficiency in the amplification transistor 124 is lowered.

Subsequently, in the low-efficiency P-phase readout K2, the switching signal FDG falls, and subsequently the reset signal RST falls. Then, the switching signal FDG rises again, and subsequently the selection signal SEL rises, and the AD conversion processing is implemented. Here, by causing the switching signal FDG to fall once before the reset signal RST falls, it is possible to couple the floating diffusion FD to the switching transistor 128. This makes it possible to boost the potential of the floating diffusion FD and readily transfer the charge from the photodiode 121.

Next, the high-efficiency P-phase readout K3 is implemented. At this time, the switching signal FDG falls, the conversion efficiency in the amplification transistor 124 is increased, and then the AD conversion processing is implemented.

Next, the high-efficiency D-phase readout K4 is implemented. At this time, the transfer signal TGL rises, and the charge of the photodiode 121 is transferred to the floating diffusion FD. Then, the transfer signal TGL falls, and subsequently the AD conversion processing is implemented. Here, in the high-efficiency D-phase readout K4, the reset signal RST is set to the low level. Therefore, the floating diffusion FD is in a floating state, making it possible to couple the floating diffusion FD to the transfer transistor 122. This makes it possible to boost the potential of the floating diffusion FD and readily extract the charge from the photodiode 121.

Next, the low-efficiency D-phase readout K5 is implemented. At this time, the switching signal FDG rises, and the conversion efficiency in the amplification transistor 124 is lowered. Subsequently, the transfer signal TGL rises, and the charge of the photodiode 121 is transferred to the floating diffusion FD. Then, the transfer signal TGL falls, the AD conversion processing is implemented, and subsequently the period transitions to the non-selection period K6. Here, by raising the transfer signal TGL after the switching signal FDG rises, it is possible to increase a capacitance as viewed from the amplification transistor 124. This makes it possible to increase the charge that can be received from the photodiode 121 and readily extract the charge accumulated in the photodiode 121.

Thus, in the ninth embodiment described above, the switching transistor 128 is provided to switch the capacitance of the floating diffusion FD as viewed from the amplification transistor 124. This makes it possible to switch the conversion efficiency in the amplification transistor 124.

### 9. Tenth Embodiment

In the ninth embodiment described above, the imaging device is provided with the pixel PIX2 that can switch the conversion efficiency. In the tenth embodiment, the pixels are provided with photodiodes having mutually different sensitivities.

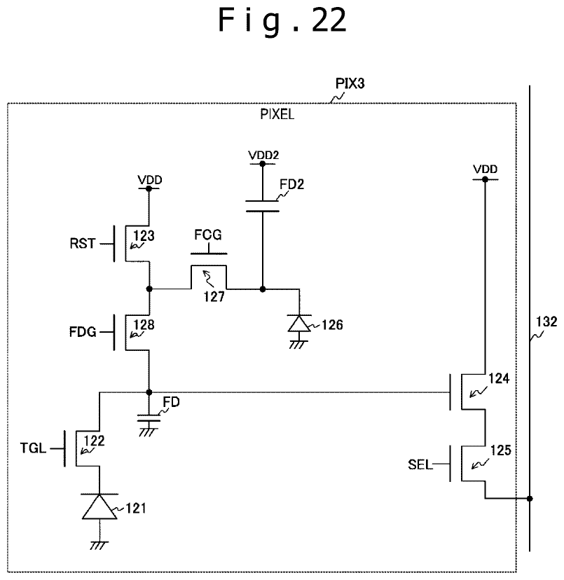

FIG. 22 is a diagram depicting a configuration example of a pixel according to the tenth embodiment.

In the drawing, this imaging device includes the pixel PIX3 instead of the pixel PIX2 of the ninth embodiment described above. Other configurations of the imaging device of the tenth embodiment are similar to the configurations of the imaging device of the ninth embodiment described above.

The pixel PIX3 is obtained by adding a photodiode 126, a path transistor 127, and a floating diffusion FD2 to the pixel PIX2 of the ninth embodiment described above. Other configurations of the pixel PIX3 of the tenth embodiment are similar to the configurations of the pixel PIX2 of the ninth embodiment described above.

The path transistor 127 sets a path through which the charge accumulated in the floating diffusion FD2 is transferred to the floating diffusion FD. The path transistor 127 is connected between the floating diffusion FD2 and a connection point of the reset transistor 123 and the switching transistor 128. A path setting signal FCG is applied to a gate of the path transistor 127.

The floating diffusion FD2 is connected between a power supply potential VDD2 and a connection point of the path transistor 127 and the photodiode 126. A planar size of the photodiode 126 can be smaller than a planar size of the photodiode 121.

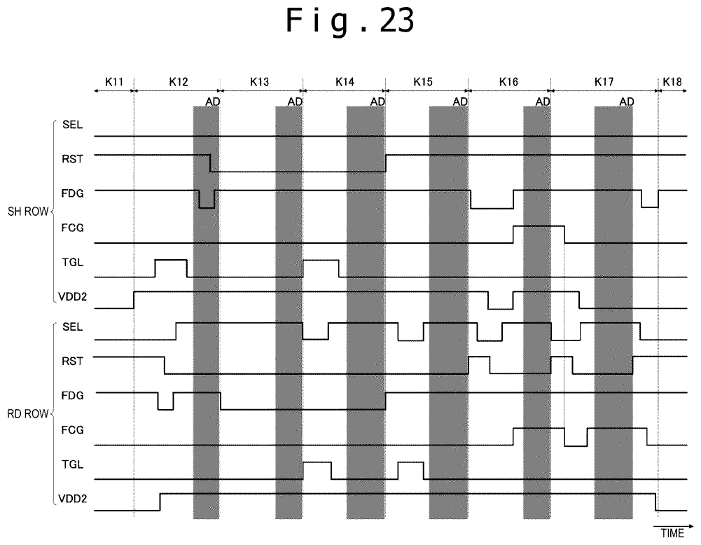

FIG. 23 is a timing chart depicting waveforms of respective sections during readout from the pixel according to the tenth embodiment.

In the drawing, in the SH rows, the selection signal SEL is set to a low level, and the selection transistor 125 is turned off. In a non-selection period K11, the transfer signal TGL and the path setting signal FCG are maintained at the low level, and the reset signal RST and the switching signal FDG are maintained at the high level. At this time, the pixel PIX3 is made highly sensitive, and the conversion efficiency in the amplification transistor 124 is lowered. Then, after the non-selection period K11 has elapsed, a low-efficiency high-sensitivity P-phase readout K12 is implemented. At this time, the transfer signal TGL rises, and the charges of the photodiode 121 and the floating diffusion FD are discharged. Further, the power supply voltage VDD2 rises and is applied to the floating diffusion FD2.

Subsequently, the transfer signal TGL falls, and subsequently the switching signal FDG falls and the reset signal RST falls. Then, the switching signal FDG rises again, and subsequently the AD conversion processing is implemented. Here, by causing the switching signal FDG to fall once before the reset signal RST falls, it is possible to couple the floating diffusion FD to the switching transistor 128. This makes it possible to boost the potential of the floating diffusion FD and readily transfer the charge from the photodiode 121.

Next, a high-efficiency high-sensitivity P-phase readout K13 is implemented. At this time, the AD conversion processing is implemented while the transfer signal TGL, the reset signal RST, the switching signal FDG, and the path setting signal FCG are maintained at levels similar to the levels after the AD conversion of the low-efficiency high-sensitivity P-phase readout K12.

Next, a high-efficiency high-sensitivity D-phase readout K14 is implemented. At this time, the transfer signal TGL rises, and the charge of the photodiode 121 is discharged. Then, the transfer signal TGL falls, and subsequently the AD conversion processing is implemented. Here, in the high-efficiency high-sensitivity D-phase readout K14, the reset signal RST is set to the low level. Therefore, the floating diffusion FD is in a floating state, making it possible to couple the floating diffusion FD to the transfer transistor 122. This makes it possible to boost the potential of the floating diffusion FD and readily extract the charge from the photodiode 121.

Next, a low-efficiency high-sensitivity D-phase readout K15 is implemented. At this time, the reset signal RST rises, and the charge of the floating diffusion FD is discharged. Then, the AD conversion processing is implemented while the level of the reset signal RST is maintained.

Next, a low-sensitivity D-phase readout K16 is implemented. At this time, the switching signal FDG falls, and subsequently the power supply voltage VDD2 falls. Then, the switching signal FDG, the path setting signal FCG, and the power supply voltage VDD2 rise, and subsequently the AD conversion processing is implemented.

Next, a low-sensitivity P-phase readout K17 is implemented. At this time, the path setting signal FCG falls, and subsequently the power supply voltage VDD2 falls and the AD conversion processing is implemented. In the low-sensitivity P-phase readout K17, the switching signal FDG falls after the AD conversion processing is implemented. After implementation of the low-sensitivity P-phase readout K17, the period transitions to a non-selection period K18. At this time, the switching signal FDG rises.

In the RD rows, in the non-selection period K11, the selection signal SEL, the transfer signal TGL, and the path setting signal FCG are maintained at the low level, and the reset signal RST and the switching signal FDG are maintained at the high level. Then, after the non-selection period K11 has elapsed, the low-efficiency high-sensitivity P-phase readout K12 is implemented. At this time, the switching signal FDG falls, and subsequently the reset signal RST falls. Then, the switching signal FDG, the selection signal SEL, and the power supply voltage VDD2 rise, and the AD conversion processing is implemented. Here, by causing the switching signal FDG to fall once before the reset signal RST falls, it is possible to couple the floating diffusion FD to the switching transistor 128. This makes it possible to boost the potential of the floating diffusion FD and readily transfer the charge from the photodiode 121.

Next, the high-efficiency high-sensitivity P-phase readout K13 is implemented. At this time, the switching signal FDG falls, the conversion efficiency in the amplification transistor 124 is increased, and then the AD conversion processing is implemented.

Next, the high-efficiency high-sensitivity D-phase readout K14 is implemented. At this time, the selection signal SEL falls, the transfer signal TGL rises, and the charge of the photodiode 121 is transferred to the floating diffusion FD. Then, the selection signal SEL rises and the transfer signal TGL falls, and subsequently the AD conversion processing is implemented. Here, in the high-efficiency high-sensitivity D-phase readout K14, the reset signal RST is set to the low level. Therefore, the floating diffusion FD is in a floating state, making it possible to couple the floating diffusion FD to the transfer transistor 122. This makes it possible to boost the potential of the floating diffusion FD and readily extract the charge from the photodiode 121.

Next, the low-efficiency high-sensitivity D-phase readout K15 is implemented. At this time, the switching signal FDG rises, and the conversion efficiency in the amplification transistor 124 is lowered. Subsequently, the selection signal SEL falls, the transfer signal TGL rises, and the charge of the photodiode 121 is transferred to the floating diffusion FD. Then, the selection signal SEL rises and the transfer signal TGL falls, and subsequently the AD conversion processing is implemented. Here, by raising the transfer signal TGL after the switching signal FDG rises, it is possible to increase a capacitance as viewed from the amplification transistor 124. This makes it possible to increase the charge that can be received from the photodiode 121 and readily extract the charge accumulated in the photodiode 121.

Next, the low-sensitivity D-phase readout K16 is implemented. At this time, the reset signal RST rises, and the charge of the floating diffusion FD2 is discharged. Here, the reset signal RST rises, and subsequently the selection signal SEL falls. Subsequently, the reset signal RST falls and then the selection signal SEL rises. Then, the path setting signal FCG rises, and subsequently the AD conversion processing is implemented.

Next, the low-sensitivity P-phase readout K17 is implemented. At this time, the reset signal RST rises, and the charge of the floating diffusion FD2 is discharged. Here, the selection signal SEL falls when the reset signal RST rises. Subsequently, the path setting signal FCG falls, and then the reset signal RST falls. Subsequently, the selection signal SEL rises and the path setting signal FCG rises. Then, the selection signal SEL rises and the path setting signal FCG rises, and subsequently the AD conversion processing is implemented. Subsequently, the set signal RST rises, and then the selection signal SEL falls. Subsequently, the path setting signal FCG falls and then the power supply voltage VDD2 falls. After the low-sensitivity P-phase readout K17 is implemented, the period transitions to the non-selection period K18.

Thus, in the tenth embodiment described above, by providing the two photodiodes 121 and 126 having mutually different sizes in the pixel PIX3, it is possible to improve a dynamic range.

### 11. Eleventh Embodiment

In the first embodiment described above, the vertical signal lines VSL1 to VSL4 and the pixels IX1 to PIX12 are connected such that the array order of the four vertical signal lines VSL1 to VSL4 and the array order of the pixels PIX1 to PIX12 provided in the column COL differ from each other. In this eleventh embodiment, semiconductor chips forming a solid-state imaging device, provided with a pixel array section in which pixels are arranged in a matrix, are layered.

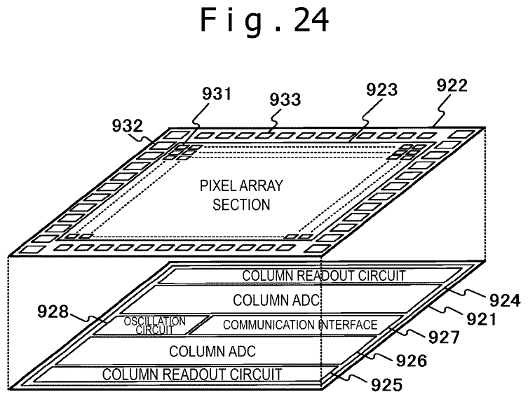

FIG. 24 is a perspective view depicting a layering example of the solid-state imaging device according to the eleventh embodiment.

In this drawing, the solid-state imaging device includes semiconductor chips 921 and 922. The semiconductor chip 922 is layered on the semiconductor chip 921.

A pixel array section 923 is formed on the semiconductor chip 922. In the pixel array section 923, pixels 931 are disposed in a matrix in the row direction and the column direction. The pixel 931 may be the pixel PIX in FIG. 3, may be the pixel PIX2 in FIG. 20, or may be the pixel PIX3 in FIG. 22. The connection between each pixel 931 and a vertical signal line may be that of any of the first to fourth embodiments described above. A pad electrode 932 and a via electrode 933 are formed around the pixel array section 923. The via electrode 933 can penetrate the semiconductor chip 922 and electrically connect the semiconductor chips 921 and 922 to each other.

A peripheral circuit 924 is formed in the semiconductor chip 921. The peripheral circuit 924 includes a column readout circuit 925, a column ADC 926, a communication interface 927, and an oscillation circuit 928. The column readout circuit 925 and the column ADC 926 may be formed so as to correspond to positions on both sides of the pixel array section 923 in the column direction. Further, any of the vertical signal lines according to the first to fourth embodiments described above may be formed in the semiconductor chip 921. Further, any of the shield lines of the fifth to eighth embodiments described above may be formed in the semiconductor chip 921.

Thus, in the eleventh embodiment described above, the semiconductor chip 922 on which the pixel array section 923 is formed is layered on the semiconductor chip 921 on which the peripheral circuit 924 is formed. This makes it possible to increase a sensitivity of the solid-state imaging device while suppressing an increase in a mounting area of the semiconductor chips forming the solid-state imaging device.

### 12. Application Example of Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

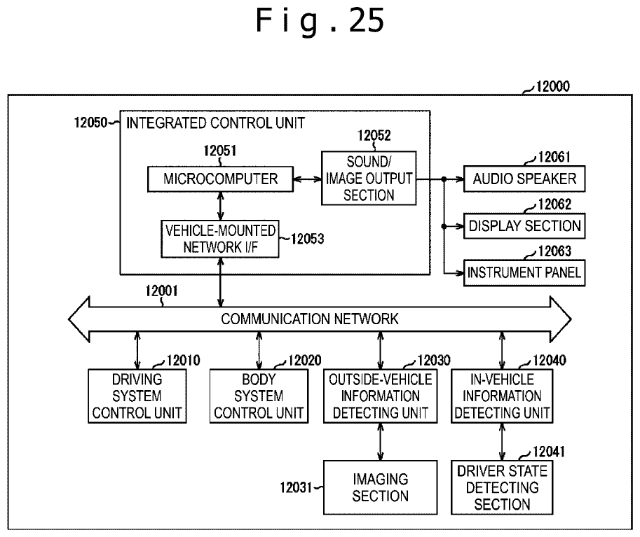

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031.

The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

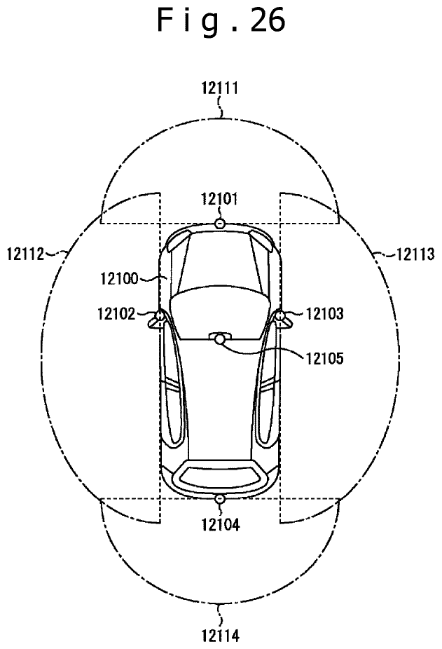

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like among the configurations described above. Specifically, for example, the imaging devices of the first to twentieth embodiments described above can be applied to the imaging section 12031 and the like. By applying the technology according to the present disclosure to the vehicle control system 12000, it is possible to reduce the crosstalk clock between the signals read out from the pixels of the pixel array section, and to improve the image quality of the imaging section 12031.

Note that the above-described embodiments illustrate examples for embodying the present technology, and the matters in the embodiments have corresponding relations with the matters specifying the invention in the scope of the claims. Similarly, the matters specifying the invention in the scope of the claims have corresponding relations with the matters in the embodiments of the present technology to which the same names are given. However, the present technology is not limited to the embodiments, and can be embodied by applying various modifications to the embodiments without departing from the gist thereof. Further, the effects described in the present specification are merely examples and are not limited, and other effects may be provided.

Note that the present technology can also adopt configurations such as the following.
(1) An imaging device including:
pixels arrayed in a matrix in a row direction and a column direction; and
a plurality of signal lines configured to transmit, simultaneously in the column direction, signals read out from pixels belonging to the same column and in mutually different rows,
wherein, in at least one column, the signal lines and the pixels are connected such that an array order of the signal lines and an array order of the pixels differ from each other.
(2) The imaging device according to (1), including
shield lines disposed between the signal lines.
(3) The imaging device according to (2),
wherein a shield line of the shield lines is disposed between signal lines adjacent to each other and connected to different color pixels.
(4) The imaging device according to (2) or (3),
wherein at least one of the shield lines is connected to a ground potential.
(5) The imaging device according to (2) or (3),
wherein at least one of the shield lines is connected to a power supply potential.
(6) The imaging device according to (2) or (3),
wherein at least one of the shield lines is divided such that a portion connected to a power supply potential is interposed between portions connected to a ground potential.
(7) The imaging device according to any one of (1) to (6),
wherein the pixels include different color pixels alternately arrayed in the column direction.
(8) The imaging device according to any one of (1) to (7),
wherein same color pixels configured to be read simultaneously in each column are connected to signal lines adjacent to each other.
(9) The imaging device according to any one of (1) to (8),
wherein the signal lines include
a first signal line connected to a first pixel,
a second signal line connected to a second pixel adjacent to the first pixel in the column direction, and
a third signal line connected to a third pixel and located between the first signal line and the second pixel.
(10) The imaging device according to any one of (1) to (9),
wherein the pixels include a first pixel, a second pixel, and a third pixel sequentially arrayed in the column direction,
the signal lines include a first signal line, a second signal line, and a third signal line sequentially arrayed in the row direction,
the first pixel is connected to the first signal line,
the second pixel is connected to the third signal line, and
the third pixel is connected to the second signal line.
(11) The imaging device according to (10),
wherein the first pixel and the third pixel are same color pixels, and
the first pixel and the second pixel are different color pixels.
(12) The imaging device according to (10) or (11),
wherein readout of signals from the first pixel, the second pixel, and the third pixel is implemented simultaneously.
(13) The imaging device according to any one of (1) to (8),
wherein the pixels adjacent to each other are connected to the same signal line.
(14) The imaging device according to any one of (1) to (8),
wherein the signal lines include
a first signal line connected to a first pixel and a second pixel adjacent to each other in the column direction,
a second signal line connected to a third pixel and a fourth pixel adjacent to each other in the column direction, and
a third signal line connected to a fifth pixel and a sixth pixel adjacent to each other in the column direction and located between the first signal line and the second pixel.
(15) The imaging device according to any one of (1) to (8),
wherein the pixels include a first pixel, a second pixel, a third pixel, a fourth pixel, a fifth pixel, and a sixth pixel sequentially arrayed in the column direction,
the signal lines include a first signal line, a second signal line, and a third signal line sequentially arrayed in the row direction,
the first pixel and the second pixel are connected to the first signal line,
the third pixel and the fourth pixel are connected to the third signal line, and
the fifth pixel and the sixth pixel are connected to the second signal line.
(16) The imaging device according to (15),
wherein readout of signals from the first pixel, the third pixel, and the fifth pixel is simultaneously implemented at a first timing, and
readout of signals from the second pixel, the fourth pixel, and the sixth pixel is simultaneously implemented at a second timing.
(17) The imaging device according to (15) or (16),
wherein the first pixel, the third pixel, and the fifth pixel are same color pixels,
the second pixel, the fourth pixel, and the sixth pixel are same color pixels, and
the first pixel and the second pixel are different color pixels.
(18) An imaging method including:
reading out signals from, among pixels arrayed in a matrix in a row direction and a column direction, pixels belonging to the same column and in mutually different rows; and
simultaneously transmitting, in the column direction, the signals read out from the pixels belonging to the same column and in mutually different rows, through a plurality of signal lines connected to the pixels in an array order mutually different from an array order of the pixels.
(19) The imaging method according to (18),
wherein pixels adjacent to each other in the column direction are different color pixels.
(20) The imaging method according to (18) or (19),
wherein a readout timing from each of the pixels is set such that different color pixels are read out at mutually different timings in each column.

### REFERENCE SIGNS LIST

100 Imaging device
101 Optical system
102 Solid-state imaging device
103 Imaging control unit
104 Image processing unit
105 Storage unit
106 Display unit
107 Operation unit
108 Bus
111 Pixel array section
112 Vertical scanning circuit
113 Column readout circuit
114 Column signal processing unit
115 Horizontal scanning circuit
116 Control circuit
121 Photodiode
122 Transfer transistor
123 Reset transistor
124 Amplification transistor
125 Selection transistor
PIX, PIX1 to PIX12 Pixel
HSL Horizontal drive line
VSL, VSL1 to VSL4 Vertical signal line
ROW1 to ROW12 Row
COL Column

What is claimed is:

1. An imaging device, comprising:
pixels arrayed in a matrix in a row direction and a column direction; and
a plurality of signal lines configured to transmit, simultaneously in the column direction, signals read out from pixels belonging to the same column and in mutually different rows,
wherein, in at least one column, the signal lines and the pixels are connected such that an array order of the signal lines and an array order of the pixels differ from each other.

2. The imaging device according to claim 1, comprising
shield lines disposed between the signal lines.

3. The imaging device according to claim 1,
wherein a shield line of the shield lines is disposed between signal lines adjacent to each other and connected to different color pixels.

4. The imaging device according to claim 1,
wherein at least one of the shield lines is connected to a ground potential.

5. The imaging device according to claim 1,
wherein at least one of the shield lines is connected to a power supply potential.

6. The imaging device according to claim 1,
wherein at least one of the shield lines is divided such that a portion connected to a power supply potential is interposed between portions connected to a ground potential.

7. The imaging device according to claim 1,
wherein the pixels include different color pixels alternately arrayed in the column direction.

8. The imaging device according to claim 1,
wherein same color pixels configured to be read simultaneously in each column are connected to signal lines adjacent to each other.

9. The imaging device according to claim 1,
wherein the signal lines include
a first signal line connected to a first pixel,
a second signal line connected to a second pixel adjacent to the first pixel in the column direction, and
a third signal line connected to a third pixel and located between the first signal line and the second pixel.

10. The imaging device according to claim 1,
wherein the pixels include a first pixel, a second pixel, and a third pixel sequentially arrayed in the column direction,
the signal lines include a first signal line, a second signal line, and a third signal line sequentially arrayed in the row direction,
the first pixel is connected to the first signal line,
the second pixel is connected to the third signal line, and
the third pixel is connected to the second signal line.

11. The imaging device according to claim 10,
wherein the first pixel and the third pixel are same color pixels, and
the first pixel and the second pixel are different color pixels.

12. The imaging device according to claim 10,
wherein readout of signals from the first pixel, the second pixel, and the third pixel is implemented simultaneously.

13. The imaging device according to claim 1,
wherein the pixels adjacent to each other are connected to the same signal line.

14. The imaging device according to claim 1,
wherein the signal lines include
a first signal line connected to a first pixel and a second pixel adjacent to each other in the column direction,
a second signal line connected to a third pixel and a fourth pixel adjacent to each other in the column direction, and
a third signal line connected to a fifth pixel and a sixth pixel adjacent to each other in the column direction and located between the first signal line and the second pixel.

15. The imaging device according to claim 1,
wherein the pixels include a first pixel, a second pixel, a third pixel, a fourth pixel, a fifth pixel, and a sixth pixel sequentially arrayed in the column direction,
the signal lines include a first signal line, a second signal line, and a third signal line sequentially arrayed in the row direction,
the first pixel and the second pixel are connected to the first signal line,
the third pixel and the fourth pixel are connected to the third signal line, and
the fifth pixel and the sixth pixel are connected to the second signal line.

16. The imaging device according to claim 15,
wherein readout of signals from the first pixel, the third pixel, and the fifth pixel is simultaneously implemented at a first timing, and
readout of signals from the second pixel, the fourth pixel, and the sixth pixel is simultaneously implemented at a second timing.

17. The imaging device according to claim 15,
wherein the first pixel, the third pixel, and the fifth pixel are same color pixels,
the second pixel, the fourth pixel, and the sixth pixel are same color pixels, and
the first pixel and the second pixel are different color pixels.

18. An imaging method, comprising:
reading out signals from, among pixels arrayed in a matrix in a row direction and a column direction, pixels belonging to the same column and in mutually different rows; and
simultaneously transmitting, in the column direction, the signals read out from the pixels belonging to the same column and in mutually different rows, through a plurality of signal lines connected to the pixels in an array order mutually different from an array order of the pixels.

19. The imaging method according to claim 18,
wherein pixels adjacent to each other in the column direction are different color pixels.

20. The imaging method according to claim 18,
wherein a readout timing from each of the pixels is set such that different color pixels are read out at mutually different timings in each column.
